(19) United States
(12) Patent Application Publication
(10) Pub. No.: US 2026/0122854 A1
(43) Pub. Date: Apr. 30, 2026

(54) EMBOSSED VAPOR CHAMBER AND SPREADER SYSTEMS

(71) Applicant: Intel Corporation, Santa Clara, CA (US)

(72) Inventors: Min Suet Lim, Penang (MY); Chi Chou Cheng, Taipei (TW); Mark Gallina, HIllsboro, OR (US); Chung Jen Ho, New Taipei (TW); Chihtsung Hu, New Taipei (TW); Jeff Ku, Taipei (TW); Shih-Yi Lai, New Taipei (TW); Chih-Hao Li, Taipei (TW); Jagadeesh Radhakrishnan, Folsom, CA (US); Ming-Sheng Tsai, Taipei (TW)

(21) Appl. No.: 19/429,428

(22) Filed: Dec. 22, 2025

(51) Int. Cl. H05K 7/20

(52) U.S. Cl. CPC H05K 7/2039

(57) ABSTRACT

A vapor chamber system may include a vapor chamber and a heat spreader disposed on the vapor chamber. The heat spreader may include a surface facing the vapor chamber. The surface may include one or more protrusions extending toward the vapor chamber. The protrusions may be configured to thermally couple the heat spreader to the vapor chamber. The protrusions may be conical or may comprise elongated wave structures including alternating upper and lower portions forming a corrugated pattern. The protrusions may define cavities between the heat spreader and the vapor chamber configured to direct airflow for enhanced heat dissipation. The vapor chamber may include upper and lower vapor chamber layers defining a vapor zone therebetween, with support pillars extending between the layers. The protrusions may be aligned with the support pillars for structural enhancement and thermal conduction.

### FIELD

The present disclosure relates to thermal management systems for electronic devices, and more particularly to vapor chamber and heat spreader assemblies with embossed features for enhanced cooling capability.

### BACKGROUND

Electronic devices, such as high-performance devices (e.g., laptops, gaming systems, desktop computers, servers, workstations, tablets, smartphones, and data center equipment) generate substantial amounts of heat during operation. As processors, graphics processing units, and other components become more powerful, the thermal loads they produce continue to increase, creating challenges for thermal management systems. Effective heat dissipation is fundamental to maintaining device performance, preventing thermal throttling, and ensuring component longevity.

Traditional cooling solutions for electronic devices typically rely on heat pipes, heat sinks, and fans to transfer heat away from heat-generating components. However, as power densities increase, conventional thermal management approaches may become insufficient to handle the thermal loads generated by modern high-performance processors and graphics cards. This has led to the development of more advanced cooling technologies, including vapor chambers, which offer enhanced heat spreading capabilities compared to traditional heat pipes.

Vapor chambers operate on the principle of phase-change heat transfer, utilizing a working fluid that evaporates at the heat source and condenses at cooler regions, creating an efficient heat transfer mechanism. The vapor chamber structure typically includes upper and lower plates that enclose a vapor zone containing the working fluid and internal support structures. While vapor chambers provide improved thermal performance over conventional heat pipes, there remains a continuing need for enhanced cooling solutions that can accommodate the increasing thermal demands of next-generation electronic devices.

Current thermal management solutions face limitations in terms of heat exchange surface area, airflow management, and overall cooling capacity. As electronic devices become thinner and more compact while simultaneously increasing in power, thermal engineers face the challenge of developing cooling solutions that can effectively dissipate heat within constrained form factors. Additionally, the need to balance thermal performance with factors such as noise levels, manufacturing cost, and mechanical reliability adds complexity to thermal system design.

The high-performance electronic device market has driven demand for advanced thermal solutions capable of handling combined processor and graphics card power levels that continue to escalate. Manufacturers seek thermal management technologies that can support higher performance levels while maintaining acceptable operating temperatures and user experience characteristics.

### BRIEF DESCRIPTION OF FIGURES

Non-limiting and non-exhaustive examples are described with reference to the following figures.

FIG. 1 illustrates a top view of a vapor chamber assembly positioned above a board, according to aspects of the present disclosure.

FIG. 2A illustrates an upper perspective view of the vapor chamber assembly of FIG. 1, according to aspects of the present disclosure.

FIG. 2B illustrates a lower perspective view of the vapor chamber assembly of FIG. 1, according to aspects of the present disclosure.

FIG. 3 illustrates an exploded view of the vapor chamber assembly of FIG. 1, according to aspects of the present disclosure.

FIG. 4 illustrates a bottom view of the vapor chamber assembly of FIG. 1, according to aspects of the present disclosure.

FIG. 5 illustrates a cross-sectional view of the vapor chamber assembly of FIG. 1, according to aspects of the present disclosure.

FIG. 6A illustrates a detailed view of a dual-sided conical support pillar, according to aspects of the present disclosure.

FIG. 6B illustrates a detailed view of a one-sided conical support pillar, according to aspects of the present disclosure.

FIG. 7A illustrates a top view of an upper vapor chamber layer, according to aspects of the present disclosure.

FIG. 7B illustrates a top view of a lower vapor chamber layer, according to aspects of the present disclosure.

FIG. 8 illustrates a top view of an alternative vapor chamber assembly, according to aspects of the present disclosure.

FIG. 9A illustrates a top perspective view of the vapor chamber assembly of FIG. 8, according to aspects of the present disclosure.

FIG. 9B illustrates a bottom perspective view of the vapor chamber assembly of FIG. 8, according to aspects of the present disclosure.

FIG. 10 illustrates an exploded view of the vapor chamber assembly of FIG. 8, according to aspects of the present disclosure.

FIG. 11 illustrates a top view of the vapor chamber assembly of FIG. 8, according to aspects of the present disclosure.

FIG. 12 illustrates a cross-sectional view of the vapor chamber assembly of FIG. 8, according to aspects of the present disclosure.

FIG. 13A illustrates a top view of an upper spreader with embossments, according to aspects of the present disclosure.

FIG. 13B illustrates a bottom view of a lower spreader with embossments, according to aspects of the present disclosure.

FIG. 14 illustrates a top view of a vapor chamber assembly with embossed wave structures, according to aspects of the present disclosure.

FIG. 15A illustrates a top view of the vapor chamber assembly of FIG. 14, according to aspects of the present disclosure.

FIG. 15B illustrates a bottom perspective view of the vapor chamber assembly of FIG. 14, according to aspects of the present disclosure.

FIG. 16 illustrates a top view of the vapor chamber assembly of FIG. 14, according to aspects of the present disclosure.

FIG. 17 illustrates a cross-sectional view of the vapor chamber assembly of FIG. 14, according to aspects of the present disclosure.

FIG. 18 illustrates a perspective view of embossed wave structures, according to aspects of the present disclosure.

FIG. 19 illustrates a top view of a heat pipe system, according to aspects of the present disclosure.

FIG. 20 illustrates a cross-sectional view of the heat pipe system of FIG. 19, according to aspects of the present disclosure.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, and components have not been described in detail to avoid unnecessarily obscuring the disclosure.

The present disclosure describes enhanced thermal management solutions for high-performance electronic devices, particularly focusing on vapor chamber assemblies with embossed features and additional spreader layers. These thermal management solutions may address the increasing cooling demands of modern electronic systems, such as high-performance laptops, gaming systems, desktop computers, servers, workstations, tablets, smartphones, data center equipment, and other computing devices that generate substantial heat during operation.

The disclosed vapor chamber assemblies may incorporate various configurations of embossments, support structures, and spreader arrangements configured to increase effective heat exchange surface area and improve cooling performance. The embossed features may be formed on vapor chamber surfaces, spreader layers, or both, creating additional thermal pathways and enhanced surface area for heat dissipation. These embossments may take various forms, including protrusions (also referred to as projections, raised features, or embossed structures). The protrusions may be conical, cylindrical, dome-shaped, pyramid-shaped, rectangular, frustum-shaped, hemispherical, wave-like, groove patterns, ribbed, corrugated, and/or one or more other shaped protruding structures. The various protrusion types/shapes may provide different thermal and structural characteristics.

The vapor chamber assemblies may include additional spreader layers positioned above and below conventional vapor chamber structures. These spreader layers may be thermally connected to the main vapor chamber body through arrays of embossed features, allowing efficient heat absorption from heat sources and further reducing junction temperatures and skin temperatures. The spreader layers may also create enclosed channels for airflow to accelerate and travel through for additional heat dissipation.

According to an aspect of the present disclosure, a vapor chamber assembly is provided. The vapor chamber assembly may include a vapor chamber having an upper vapor chamber layer and a lower vapor chamber layer defining a vapor zone therebetween. The vapor chamber assembly may include an upper spreader positioned above the upper vapor chamber layer. The upper vapor chamber layer may include a plurality of embossments extending upward from the upper vapor chamber layer toward the upper spreader. The vapor chamber assembly may include a lower spreader positioned below the lower vapor chamber layer. The lower vapor chamber layer may include one or more (e.g., a plurality of) protrusions/projections, such as one or more embossments, extending downward from the lower vapor chamber layer toward the lower spreader. The vapor chamber assembly may include a plurality of conical support pillars extending through the vapor zone between the upper vapor chamber layer and the lower vapor chamber layer.

According to other aspects of the present disclosure, the vapor chamber assembly may include one or more of the following features. The plurality of conical support pillars may include one-sided conical support pillars extending from the lower vapor chamber layer and connecting to the upper spreader. The plurality of conical support pillars may include dual-sided conical support pillars extending from both the upper vapor chamber layer and the lower vapor chamber layer. Each conical support pillar may include a cylindrical body and at least one conical portion. The embossments of the upper vapor chamber layer may create cavities between the upper spreader and the upper vapor chamber layer for airflow. The embossments of the lower vapor chamber layer may create cavities between the lower spreader and the lower vapor chamber layer for airflow. The vapor chamber assembly may include at least one pedestal extending from the lower spreader for thermal contact with a heat source. The upper spreader and lower spreader may be thermally connected to the vapor chamber through the embossments.

According to another aspect of the present disclosure, a vapor chamber assembly is provided. The vapor chamber assembly may include a vapor chamber having an upper vapor chamber layer and a lower vapor chamber layer. The vapor chamber assembly may include an upper spreader positioned above the vapor chamber. The upper spreader may include a plurality of embossments extending downward toward the upper vapor chamber layer. The vapor chamber assembly may include a lower spreader positioned below the vapor chamber. The lower spreader may include a plurality of embossments extending upward toward the lower vapor chamber layer.

According to other aspects of the present disclosure, the vapor chamber assembly may include one or more of the following features. The embossments of the upper spreader may be thermally connected to the upper vapor chamber layer through connection points. The embossments of the lower spreader may be thermally connected to the lower vapor chamber layer through connection points. The connection points may be solder joints. The embossments may create enclosed air flow channels between the spreaders and the vapor chamber layers. The vapor chamber may include a plurality of support pillars extending between the upper vapor chamber layer and the lower vapor chamber layer. The embossments may be aligned with the support pillars for structural enhancement.

According to another aspect of the present disclosure, a vapor chamber assembly is provided. The vapor chamber assembly may include a vapor chamber. The vapor chamber assembly may include an upper heat spreader positioned above the vapor chamber. The upper heat spreader may include embossed wave structures extending across portions of the vapor chamber. The embossed wave structures include alternating upper portions and lower portions forming a corrugated pattern.

The embossed wave structures may be oriented diagonally to create angled channels for airflow. The embossed wave structures may include planar portions connecting the upper portions and lower portions. The vapor chamber assembly may include a lower spreader positioned below the vapor chamber with embossments extending toward the vapor chamber. The embossed wave structures may create enclosed channels that facilitate airflow across surfaces of the vapor chamber assembly. The embossed wave structures may increase the effective heat-exchange surface area for enhanced thermal dissipation.

Various aspects described herein may incorporate different types of support structures within the vapor chambers. Some configurations may utilize extended support members (e.g., pillars) that serve dual functions as structural elements and thermal conduction paths. Other configurations may employ separate embossed features on spreader layers that interface with conventional vapor chamber designs. The support structures may include one-sided conical support pillars, dual-sided conical support pillars, or combinations thereof, depending on the specific thermal and mechanical requirements of the application.

The various aspects and features disclosed herein may be combined in different ways to achieve desired thermal performance characteristics. For example, heat spreaders with different embossment types may be used together in a single assembly, or embossed spreaders may be combined with vapor chambers that also have embossed features. The modular nature of these thermal management solutions allows for customization based on specific application requirements, available space constraints, and thermal dissipation needs.

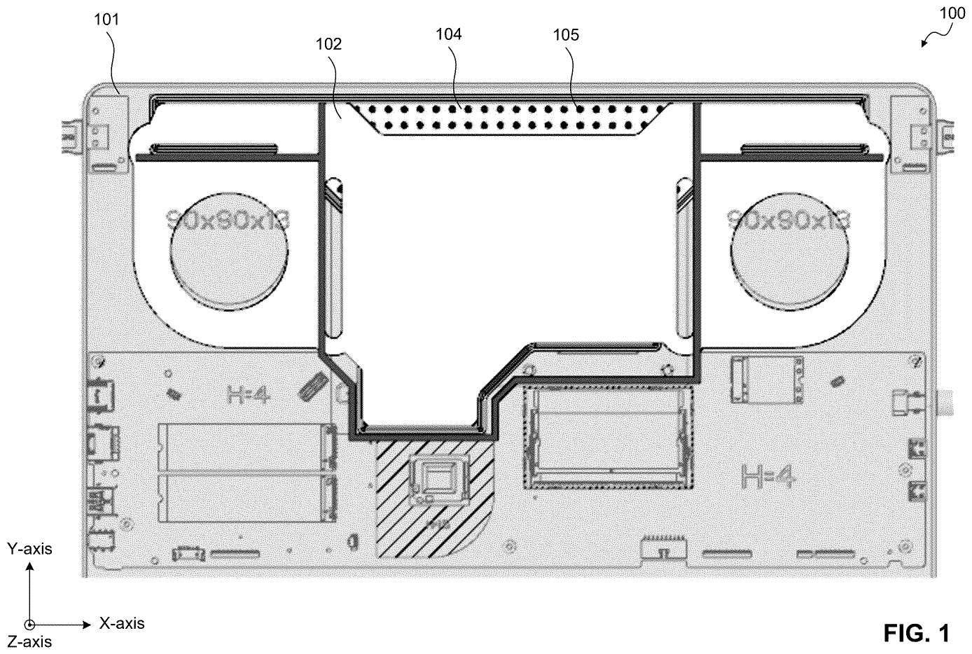

Referring to FIG. 1, a vapor chamber assembly 100 may be positioned on a board 101 to provide thermal management for electronic components. The vapor chamber assembly 100 may include an upper spreader 102 that forms a top layer of the thermal management structure. A vapor chamber 104 may be positioned beneath the upper spreader 102 and may occupy a central region of the assembly. The vapor chamber 104 may feature one or more embossments 105, such as on the upper surface and/or lower surface opposite the upper surface, of the vapor chamber 104. The embossments 105 may be arranged in a defined pattern or randomly positioned.

The embossments 105 may appear as circular or conical features arranged in rows throughout a central area of the vapor chamber 104. In some cases, the embossments 105 may provide thermal connection points between the upper spreader 102 and the vapor chamber 104 to facilitate heat transfer and dissipation from heat sources positioned on the board 101. The vapor chamber assembly 100 may be positioned centrally on the board 101, with the embossments 105 creating enhanced thermal pathways for improved cooling performance.

The embossments 105 may take various geometric configurations beyond the conical shapes shown in the figures. For example, the embossments 105 may be conical, cylindrical, dome-shaped, pyramid-shaped, rectangular, frustum-shaped, and/or have other three-dimensional profiles that provide thermal connectivity and structural support. The distribution pattern of the embossments 105 across the vapor chamber 104 surface may be arranged to optimize heat transfer characteristics while maintaining structural integrity of the vapor chamber assembly 100. The upper spreader 102, vapor chamber 104 (layer 302 and 304, and/or support pillars 306, 308), and/or lower spreader 106 may be made of copper, aluminum, silver, nickel, titanium, stainless steel, copper alloys, aluminum alloys, graphite, carbon composites, metal matrix composites, or other thermally conductive materials.

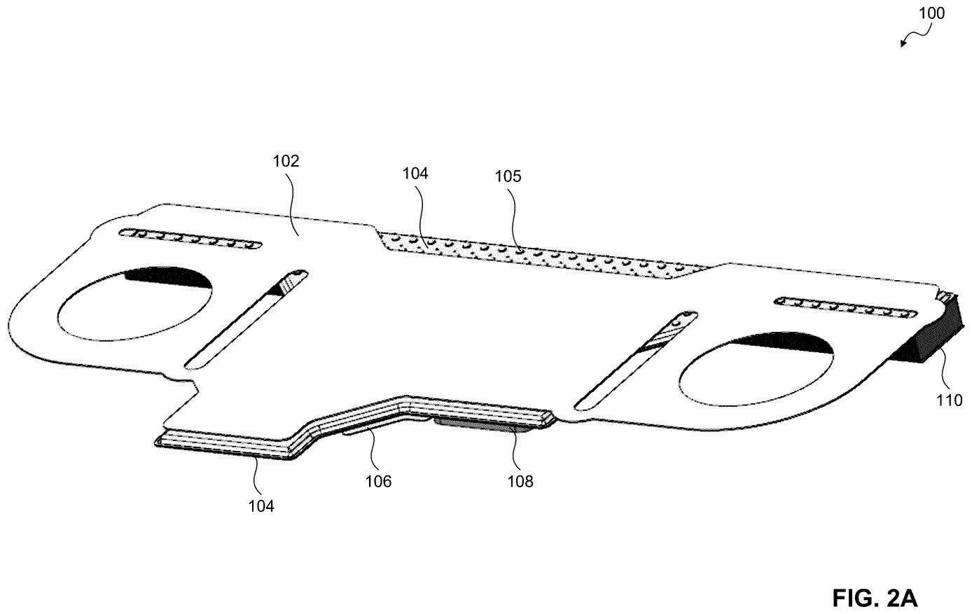

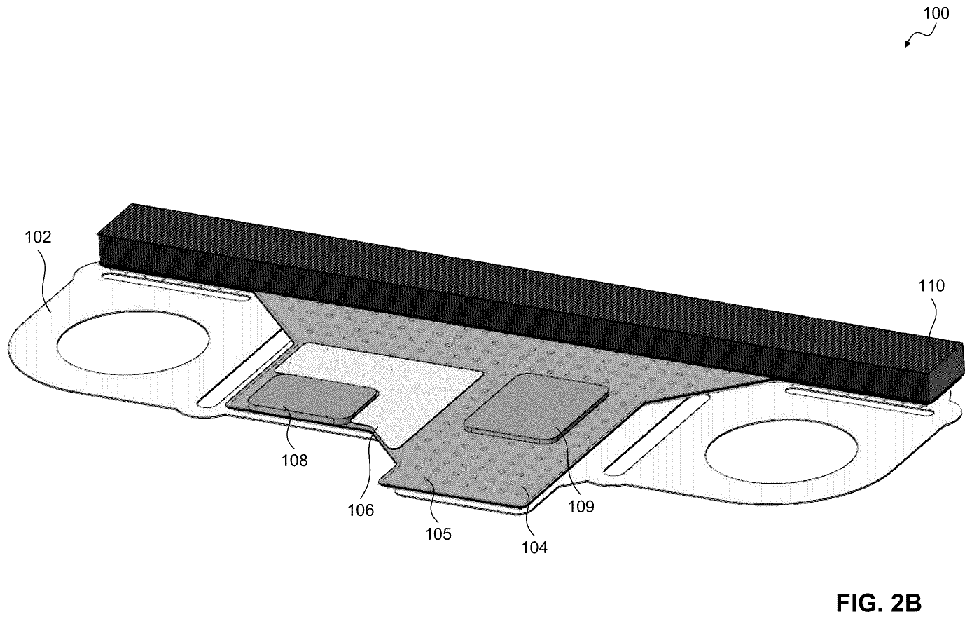

With reference to FIGS. 2A and 2B, the vapor chamber assembly 100 may incorporate additional thermal management components that work in conjunction with the embossed vapor chamber structure. A lower spreader 106 may be positioned beneath the vapor chamber 104 to provide additional heat spreading capability. In some cases, a pedestal 108, 109 may be integrated with the assembly to facilitate thermal contact with specific heat-generating components on the board 101. A heat spreader 110 may also be included as part of the thermal management system to extend the effective cooling area beyond the immediate footprint of the vapor chamber assembly 100.

Referring to FIG. 2A, an upper perspective view of the vapor chamber assembly 100 illustrates the layered configuration and thermal management components. The upper spreader 102 may be positioned at the top of the structure, with the vapor chamber 104 located beneath the upper spreader 102. The vapor chamber 104 may feature multiple embossments 105 distributed across the upper surface in a regular pattern. The embossments 105 may appear as raised protrusions extending upward from the vapor chamber 104, creating thermal connection points and enhanced surface area for heat transfer.

The lower spreader 106 may be positioned beneath the vapor chamber 104, forming an additional layer of the thermal management assembly. A pedestal 108 may be positioned on the lower spreader 106, providing a thermal contact interface for heat-generating components. The pedestal 108 may be configured to make direct thermal contact with electronic devices or processors mounted on the board 101. Adjacent to the pedestal 108, the heat spreader 110 may extend from a side of the vapor chamber assembly 100. The heat spreader 110 may feature a corrugated or finned structure with parallel ridges for enhanced heat dissipation capability.

The vapor chamber assembly 100 may provide a thermal management solution where the embossments 105 create thermal connection points between the spreader layers while also forming enclosed channels that facilitate airflow through the assembly for improved cooling performance. The arrangement of the upper spreader 102, vapor chamber 104, and lower spreader 106 may create a multi-layer thermal management structure that increases the effective heat exchange surface area compared to conventional vapor chamber designs.

With reference to FIG. 2B, a lower perspective view of the vapor chamber assembly 100 shows the arrangement and relationship of components from the bottom side of the assembly. The heat spreader 110 may be positioned at the top of the view, featuring a corrugated or finned structure for enhanced heat dissipation. The heat spreader 110 may be disposed on the upper spreader 102, which may appear as a flat plate with mounting holes at the ends for attachment to the overall thermal management system.

The upper spreader 102 may be positioned above the vapor chamber 104, which may be shown in a cyan color and may include multiple components mounted on the lower surface. The vapor chamber 104 may have the pedestal 108 and a pedestal 109 attached to the lower surface, along with an embossment 105. The pedestals 108, 109 may provide thermal contact points for heat-generating components positioned on the board 101. The pedestal 109 may be configured similarly to the pedestal 108 to facilitate thermal transfer from electronic devices or processors.

The lower spreader 106 may form the bottom layer of the assembly, providing additional heat spreading capability and structural support for the vapor chamber assembly 100. The layered configuration shown in the lower perspective view demonstrates how the various components may be stacked and aligned to form a complete thermal management structure. The embossments 105 and pedestals 108, 109 may be positioned to optimize thermal conduction pathways while maintaining structural integrity of the vapor chamber assembly 100.

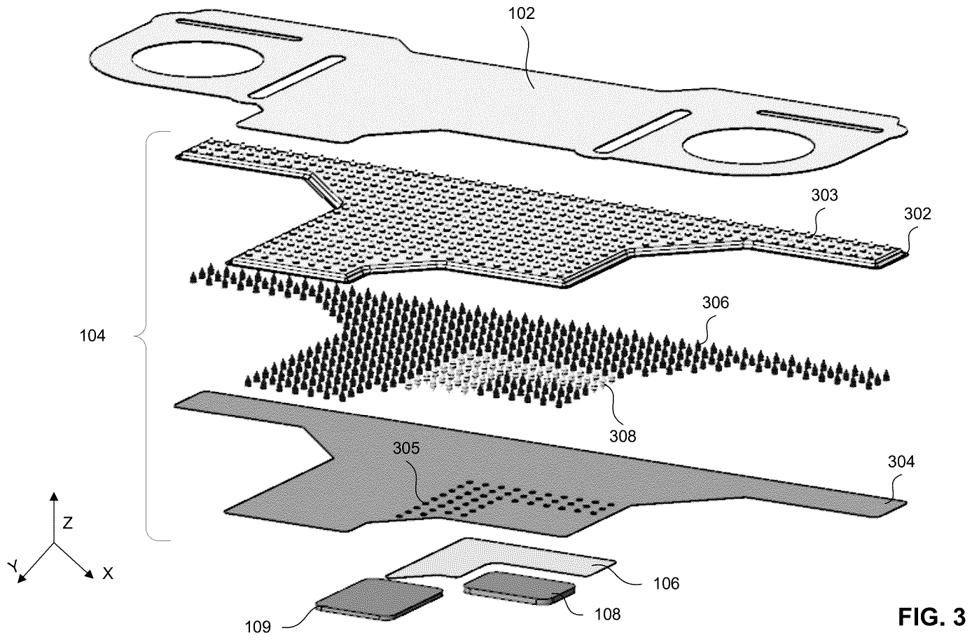

Referring to FIG. 3, an exploded view of the vapor chamber assembly 100 illustrates the layered construction and internal structure of the thermal management system. The vapor chamber assembly 100 may comprise multiple discrete layers that assemble together to form a complete vapor chamber structure with enhanced thermal performance characteristics. The exploded view demonstrates the relationship and arrangement of the various components that make up the vapor chamber assembly 100.

The vapor chamber 104 may include an upper vapor chamber layer 302 positioned in the upper portion of the vapor chamber structure. The upper vapor chamber layer 302 may include one or more embossments 303 projecting from the surface of the layer 302. The embossment(s) 303 may be formed as conical, cylindrical, dome-shaped, pyramid-shaped, rectangular, frustum-shaped, and/or other three-dimensional protrusions that extend from the upper vapor chamber layer 302. In some cases, multiple embossments 303 may be distributed across the surface of the upper vapor chamber layer 302 in a defined or random pattern to provide thermal connectivity and structural support within the vapor chamber assembly 100. The pattern may be configured to correspond to the shape of the component (e.g., heat spreader 102 and/or 106 in contact with the vapor chamber 104.

A lower vapor chamber layer 304 may be positioned beneath the upper vapor chamber layer 302 to form the lower portion of the vapor chamber structure of the vapor chamber 104. The lower vapor chamber layer 304 may include one or more embossments 305 that extend from the surface of the layer 304. The embossment(s) 305 may be configured similarly to the embossment(s) 303 of the upper vapor chamber layer 302, providing thermal connection points and structural features. The embossments 305 may be arranged in a pattern that corresponds to or complements the arrangement of the embossments 303 on the upper vapor chamber layer 302 and/or to an adjacent component. The layer 302 and 304 may together define the vapor zone of the vapor chamber 104. For example, the layers 302 and 304 may be sealed (e.g., hermetically) sealed together to enclose the vapor zone therebetween.

The vapor chamber 104 may include one or more support structures that extend between the upper vapor chamber layer 302 and the lower vapor chamber layer 304. A one-sided conical support pillar 306 may extend from one of the vapor chamber layers toward the other layer, providing structural support and thermal conduction pathways. The one-sided conical support pillar 306 may feature a conical portion that interfaces with the embossments 303 or 305 of the respective vapor chamber layers. For example, the embossments 303 or 305 may form a cavity or depression configured to receive/accommodate the conical portion. In some cases, the one-sided conical support pillar 306 may be used across most of the vapor chamber surface, where the gap to a cover is sufficient for the pillar configuration.

A dual-sided conical support pillar 308 may extend in both directions from a central position, connecting both the upper vapor chamber layer 302 and the lower vapor chamber layer 304. The dual-sided conical support pillar 308 may feature conical portions at both ends that interface with the embossments 303 and 305 of the respective vapor chamber layers 302, 304. For example, the embossments 303 and/or 305 may form a respective cavity or depression configured to receive/accommodate the corresponding conical portion of the embossments 303, 305. The dual-sided conical support pillar 308 may be applied in areas where the board 101 has no tall components, allowing for the extended pillar structure without interference from electronic components mounted on the board 101.

The support pillars 306, 308 may have various geometric configurations beyond the conical shapes illustrated in the figures. For example, the support pillars 306, 308 may be conical, cylindrical, dome-shaped, pyramid-shaped, rectangular, frustum-shaped, hemispherical, and/or have other three-dimensional profiles that provide structural support and thermal connectivity. In some cases, the dual-sided conical support pillar 308 may have different shapes on each end, such as a conical shape on one end and a different geometric shape on the other end, allowing for customized interface characteristics with the respective vapor chamber layers.

The layered construction shown in the exploded view demonstrates how the upper vapor chamber layer 302, lower vapor chamber layer 304, and support pillars 306, 308 assemble together to form the vapor chamber 104. The upper spreader 102 may be positioned above the upper vapor chamber layer 302, while the lower spreader 106 may be positioned beneath the lower vapor chamber layer 304. The pedestals 108, 109 may be attached to the lower vapor chamber layer 304 and/or lower spreader 106 to provide thermal contact interfaces with heat-generating components on the board 101.

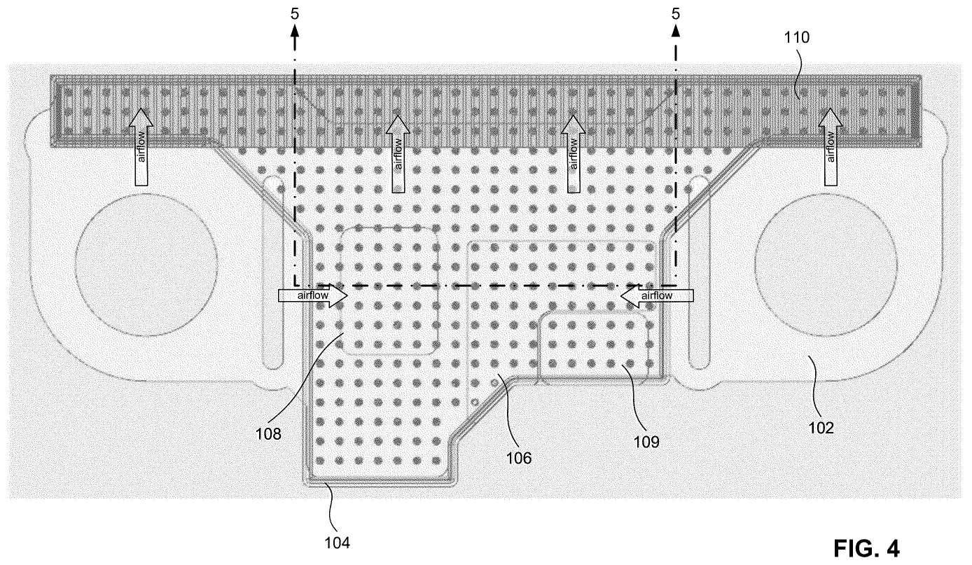

Referring to FIG. 4, a bottom view of the vapor chamber assembly 100 illustrates the arrangement of thermal management components and airflow characteristics of the thermal management system. The vapor chamber assembly 100 may be positioned above the board 101, with various components arranged to facilitate enhanced heat dissipation and airflow management. The bottom view provides visibility of the structural arrangement and thermal interface components that may be positioned on the lower side of the vapor chamber assembly 100.

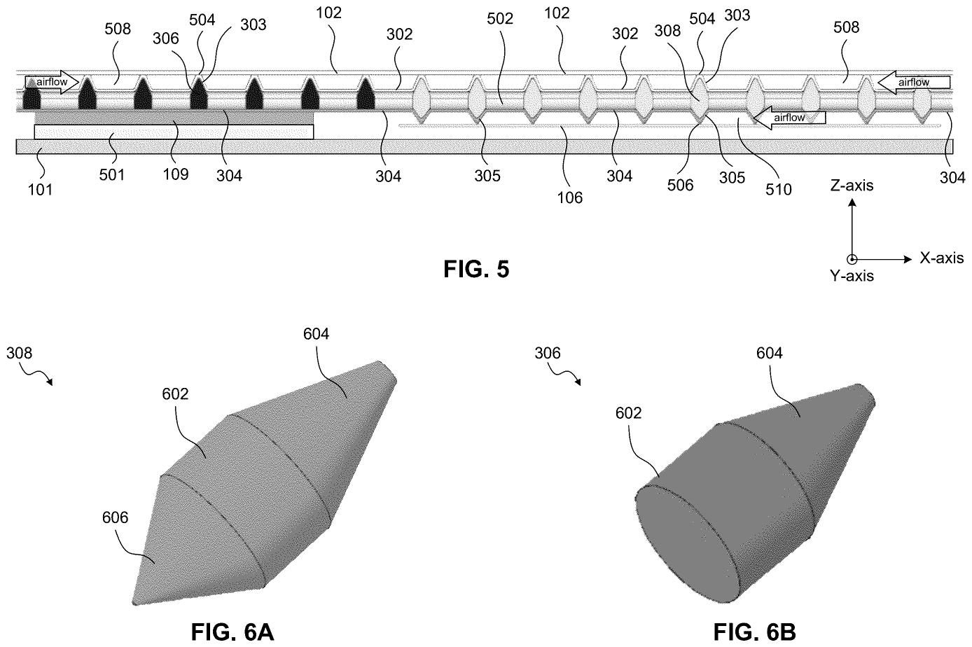

The cross-sectional view illustrated in FIG. 5 is taken along the cross-section line 5-5 shown in dashed lines through the vapor chamber assembly 100. The cross-section line 5-5 may correspond to a sectional plane that reveals internal structural details and component relationships within the vapor chamber assembly 100. As shown, the cross-section 5-5 is positioned to intersect various thermal management components, including the vapor chamber 104, the upper spreader 102, and the lower spreader 106, providing a reference for detailed internal views of the assembly structure.

The vapor chamber assembly 100 may feature an array of embossed features represented by distributed elements across a central region of the assembly. The embossments 105 may create thermal connection points between the spreader layers while also contributing to the overall structural integrity of the vapor chamber assembly 100. The embossments 105 may be arranged in a pattern that optimizes thermal transfer characteristics while accommodating the airflow paths through the assembly.

Airflow paths may be indicated by arrows showing the direction of air movement through the vapor chamber assembly 100. The arrows may point horizontally across a central region of the assembly and vertically along the sides, demonstrating how air may move through the thermal management structure. The horizontal airflow paths may facilitate air movement across the surfaces of the vapor chamber 104 and spreader layers, while the vertical airflow paths may allow air to move through enclosed channels formed by the layered construction of the vapor chamber assembly 100.

The airflow paths may be configured to enhance cooling performance by directing air through enclosed channels created by the upper spreader 102 and lower spreader 106 in combination with the vapor chamber 104. Air may enter the vapor chamber assembly 100 from one side and travel through the enclosed channels, making thermal contact with the embossed surfaces and spreader layers before exiting from another side of the assembly. The airflow may accelerate as the air travels through the enclosed channels, increasing heat transfer coefficients and improving overall thermal dissipation performance.

The heat spreader 110 may be positioned in an upper region of the bottom view, providing an extended surface for heat dissipation. The heat spreader 110 may feature a finned or corrugated structure that increases the effective surface area available for heat transfer to the surrounding air. The positioning of the heat spreader 110 may allow for additional thermal management capability beyond the immediate footprint of the vapor chamber 104, extending the cooling capacity of the overall thermal management system.

The pedestals 108, 109 may be visible in the bottom view, positioned to provide thermal contact interfaces with heat-generating components mounted on the board 101. The pedestals 108, 109 may be strategically located to align with processors, graphics processing units, memory modules, voltage regulators, power management integrated circuits, system-on-chip devices, application-specific integrated circuits, field-programmable gate arrays, or other electronic components that generate substantial heat during operation. The thermal interface provided by the pedestals 108, 109 may facilitate efficient heat transfer from the heat sources to the vapor chamber assembly 100, where the heat may be distributed and dissipated through the enhanced surface area and airflow channels of the thermal management structure.

Referring to FIGS. 5, 6A, and 6B, a cross-sectional view of the vapor chamber assembly 100 reveals the internal structure and component relationships within the thermal management system. The vapor chamber assembly 100 may be positioned on the board 101, with the vapor chamber 104 comprising the upper vapor chamber layer 302 and the lower vapor chamber layer 304. A vapor zone 502 may be defined between the upper vapor chamber layer 302 and the lower vapor chamber layer 304, creating an internal space where phase-change heat transfer occurs during operation of the vapor chamber assembly 100.

The vapor zone 502 may contain working fluid that undergoes phase transitions to facilitate heat transfer within the vapor chamber 104. The vapor zone 502 may be sealed (e.g., hermetically sealed) between the upper vapor chamber layer 302 and the lower vapor chamber layer 304, maintaining the working fluid in a controlled environment for thermal management operations. The dimensions and configuration of the vapor zone 502 may be configured to optimize heat transfer characteristics while accommodating the structural support elements within the vapor chamber 104.

A support pillar 501 may be positioned within the vapor zone 502 to provide structural support between the upper vapor chamber layer 302 and the lower vapor chamber layer 304. The support pillar 501 may extend through the vapor zone 502, connecting the upper and lower vapor chamber layers to maintain structural integrity of the vapor chamber 104. In some cases, multiple support pillars 501 may be distributed throughout the vapor zone 502 to provide adequate structural support while allowing for working fluid circulation within the vapor chamber 104.

The one-sided conical support pillar 306 may extend upward from the lower vapor chamber layer 304 and may connect to the upper spreader 102 positioned above the upper vapor chamber layer 302. A connection point 504 may be formed where the one-sided conical support pillar 306 interfaces with the upper spreader 102, creating a thermal and mechanical connection between these components. The connection point 504 may facilitate heat transfer from the vapor chamber 104 to the upper spreader 102 while providing structural support for the layered assembly.

The dual-sided conical support pillar 308 may extend both upward and downward from a central position within the vapor zone 502. The dual-sided conical support pillar 308 may connect the upper spreader 102 above and the lower spreader 106 below through respective connection interfaces. A connection point 506 may be formed where the dual-sided conical support pillar 308 interfaces with the lower spreader 106, creating thermal and mechanical connections between the vapor chamber 104 and the lower spreader 106. The connection point 506 may facilitate heat transfer from the vapor chamber 104 to the lower spreader 106.

A cavity 508 may be formed between the upper spreader 102 and the upper vapor chamber layer 302, creating an enclosed channel for airflow management. The cavity 508 may extend across portions of the upper surface of the vapor chamber assembly 100, providing space for air to flow and make thermal contact with the surfaces of the upper spreader 102 and the upper vapor chamber layer 302. The cavity 508 may be configured to allow inbound airflow to accelerate and travel through the enclosed channel for additional heat dissipation from the thermal management system.

A cavity 510 may be formed between the lower vapor chamber layer 304 and the lower spreader 106, creating an additional enclosed channel for airflow. The cavity 510 may extend across portions of the lower surface of the vapor chamber assembly 100, providing space for air circulation and thermal contact with the surfaces of the lower vapor chamber layer 304 and the lower spreader 106. The cavity 510 may work in conjunction with the cavity 508 to create a comprehensive airflow management system that enhances heat dissipation performance of the vapor chamber assembly 100.

The spreader layers may create enclosed channels for inbound airflow to accelerate and travel through for additional heat dissipation. The upper spreader 102 and the lower spreader 106 may form enclosed airflow channels in combination with the vapor chamber 104, allowing air to enter the thermal management system and travel through the cavities 508 and 510. The enclosed channels may direct airflow across the embossed surfaces and thermal interface areas, increasing heat transfer coefficients and improving overall cooling performance of the vapor chamber assembly 100.

With reference to FIGS. 6A and 6B, detailed views of the support pillar structures illustrate the geometric configurations of the thermal and structural connection elements. The dual-sided conical support pillar 308 may include a cylindrical body 602 that forms a central portion of the support structure. The cylindrical body 602 may provide structural continuity and thermal conduction pathways between the upper and lower portions of the dual-sided conical support pillar 308.

A conical portion 604 may be positioned at an upper end of the cylindrical body 602, extending toward the upper spreader 102. The conical portion 604 may be configured to interface with the embossment 303 of the upper vapor chamber layer 302 or with corresponding features of the upper spreader 102. The conical portion 604 may provide a tapered interface that facilitates thermal contact and mechanical connection while accommodating manufacturing tolerances and assembly variations.

A conical portion 606 may be positioned at a lower end of the cylindrical body 602, extending toward the lower spreader 106. The conical portion 606 may be configured to interface with the embossment 305 of the lower vapor chamber layer 304 or with corresponding features of the lower spreader 106. The conical portion 606 may provide thermal and mechanical interface characteristics similar to the conical portion 604, creating a dual-ended support structure that connects multiple layers of the vapor chamber assembly 100.

The one-sided conical support pillar 306 may include the cylindrical body 602 and a single conical portion 604 at one end, as shown in FIG. 6B. The one-sided configuration may be used in areas where clearance constraints or component placement considerations limit the available space for dual-sided support structures. The one-sided conical support pillar 306 may provide structural support and thermal conduction pathways while accommodating different clearance requirements on either side of the vapor chamber assembly 100.

The support pillars 306, 308 may have various geometric configurations beyond the conical and cylindrical shapes illustrated in the figures. The support pillars 306, 308 may be conical, cylindrical, dome-shaped, pyramid-shaped, rectangular, frustum-shaped, hemispherical, or have other three-dimensional profiles that provide structural support and thermal connectivity. The cylindrical body 602 may be replaced with other geometric shapes such as rectangular, hexagonal, or other cross-sectional configurations that provide structural continuity between the conical portions 604, 606.

For dual-sided support pillars 308, each end may have a different shape from the other end, allowing for customized interface characteristics with the respective vapor chamber layers or spreader components. For example, the conical portion 604 may have a different cone angle, height, or base diameter compared to the conical portion 606, accommodating different thermal or mechanical requirements at each interface. The geometric variations may be selected based on thermal performance requirements, structural load considerations, and manufacturing constraints of the vapor chamber assembly 100.

The embossments 303 and 305 may create the cavities 508 and 510 for airflow by forming raised or recessed features that establish spacing between the spreader layers and the vapor chamber layers. The embossments 303 of the upper vapor chamber layer 302 may extend toward the upper spreader 102, creating the cavity 508 in the spaces between the embossed features. Similarly, the embossments 305 of the lower vapor chamber layer 304 may extend toward the lower spreader 106, creating the cavity 510 in the spaces between the embossed features.

The conical support pillars 306, 308 may provide structural support and thermal conduction paths within the vapor chamber assembly 100. The conical support pillars 306, 308 may transfer mechanical loads between the spreader layers and the vapor chamber layers while also conducting heat through the thermal pathways created by the metallic construction of the support structures. The thermal conduction paths may supplement the phase-change heat transfer occurring within the vapor zone 502, providing additional thermal management capability for the vapor chamber assembly 100.

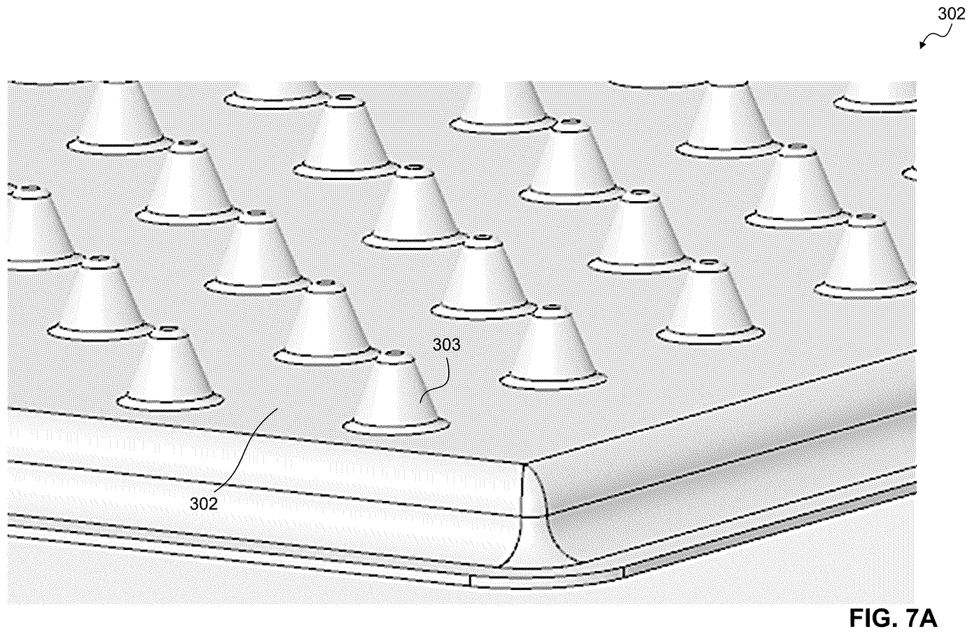

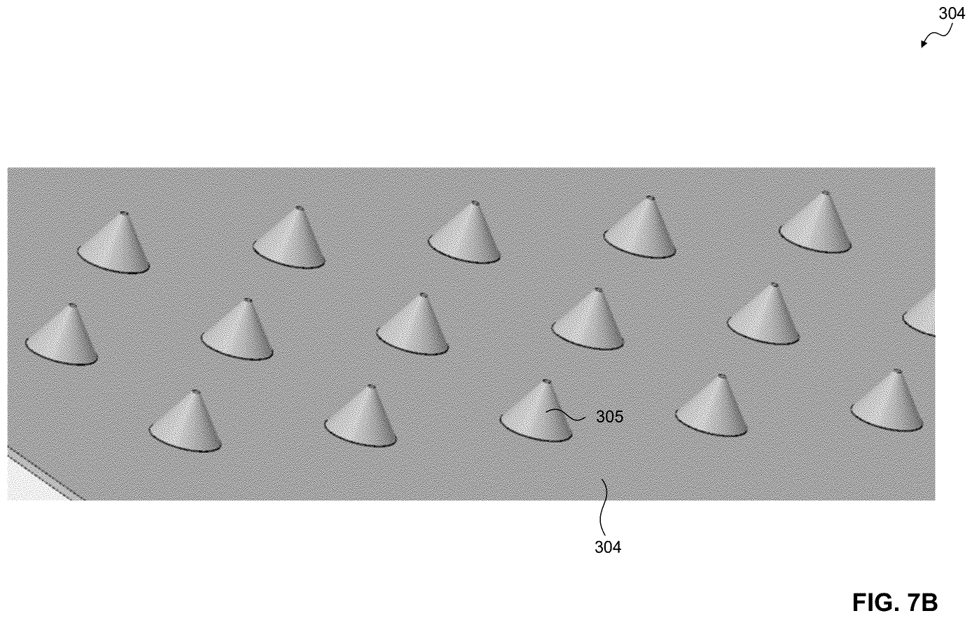

Referring to FIG. 7A, a top view of the upper vapor chamber layer 302 illustrates the surface configuration and embossment arrangement of the upper portion of the vapor chamber structure. The upper vapor chamber layer 302 may form a planar structure that defines the upper boundary of the vapor zone within the vapor chamber assembly. The upper vapor chamber layer 302 may be configured to contain working fluid and facilitate phase-change heat transfer processes during thermal management operations.

The upper vapor chamber layer 302 may include multiple embossments 303 distributed across the surface in a defined arrangement. The embossments 303 may be positioned at regular intervals across the upper vapor chamber layer 302, creating a structured array that covers the surface area of the layer. The regular pattern of the embossments 303 may be configured to optimize thermal transfer characteristics while providing structural support for the vapor chamber assembly. The spacing and distribution of the embossments 303 may be selected based on thermal performance requirements, structural load considerations, and manufacturing constraints.

Each embossment 303 may appear as a conical or dome-shaped protrusion extending from the surface of the upper vapor chamber layer 302. The embossments 303 may provide thermal connection points that facilitate heat transfer between the upper vapor chamber layer 302 and adjacent components such as the upper spreader or support structures. The embossments 303 may also provide structural support features that maintain the spacing and alignment of components within the vapor chamber assembly while accommodating thermal expansion and mechanical loads during operation.

The arrangement of the embossments 303 may allow for efficient thermal conduction pathways while maintaining the structural integrity of the upper vapor chamber layer 302. The embossments 303 may be positioned to correspond with support structures or thermal interface components, creating aligned thermal pathways that enhance heat transfer performance. The regular pattern of the embossments 303 may also facilitate manufacturing processes by providing consistent geometric features that may be formed using standard fabrication techniques.

With reference to FIG. 7B, a top view of the lower vapor chamber layer 304 shows the surface configuration and embossment distribution of the lower portion of the vapor chamber structure. The lower vapor chamber layer 304 may form a planar surface that defines the lower boundary of the vapor zone and provides structural support for the vapor chamber assembly. The lower vapor chamber layer 304 may be configured to work in conjunction with the upper vapor chamber layer 302 to contain working fluid and facilitate thermal management operations.

The lower vapor chamber layer 304 may include multiple embossments 305 distributed across the surface in a regular pattern. The embossments 305 may be arranged in rows and columns, forming an array of raised features that extend from the planar surface of the lower vapor chamber layer 304. The distribution pattern of the embossments 305 may correspond to or complement the arrangement of the embossments 303 on the upper vapor chamber layer 302, creating aligned thermal and structural pathways through the vapor chamber assembly.

Each embossment 305 may appear as a conical or dome-shaped protrusion extending from the surface of the lower vapor chamber layer 304. The embossments 305 may provide structural support and thermal connection points for the vapor chamber assembly, facilitating heat transfer between the lower vapor chamber layer 304 and adjacent components such as the lower spreader or support structures. The embossments 305 may be configured to interface with support pillars or other thermal management components, creating thermal conduction pathways that supplement the phase-change heat transfer occurring within the vapor zone.

The regular pattern and spacing of the embossments 305 may be selected to optimize thermal performance while maintaining structural integrity of the lower vapor chamber layer 304. The embossments 305 may be positioned to align with corresponding features on the upper vapor chamber layer 302 or with external thermal management components, creating coordinated thermal pathways through the vapor chamber assembly. The arrangement of the embossments 305 may also accommodate the placement of support structures and thermal interface components while providing adequate surface area for heat transfer operations.

The embossments 303 and 305 on the respective vapor chamber layers may create enhanced surface area for heat transfer within the vapor chamber assembly. The raised features may increase the effective surface area available for thermal contact with working fluid, support structures, and adjacent thermal management components. The embossments 303 and 305 may also provide structural reinforcement for the vapor chamber layers, distributing mechanical loads and maintaining the dimensional stability of the vapor chamber assembly during thermal cycling and operational stresses.

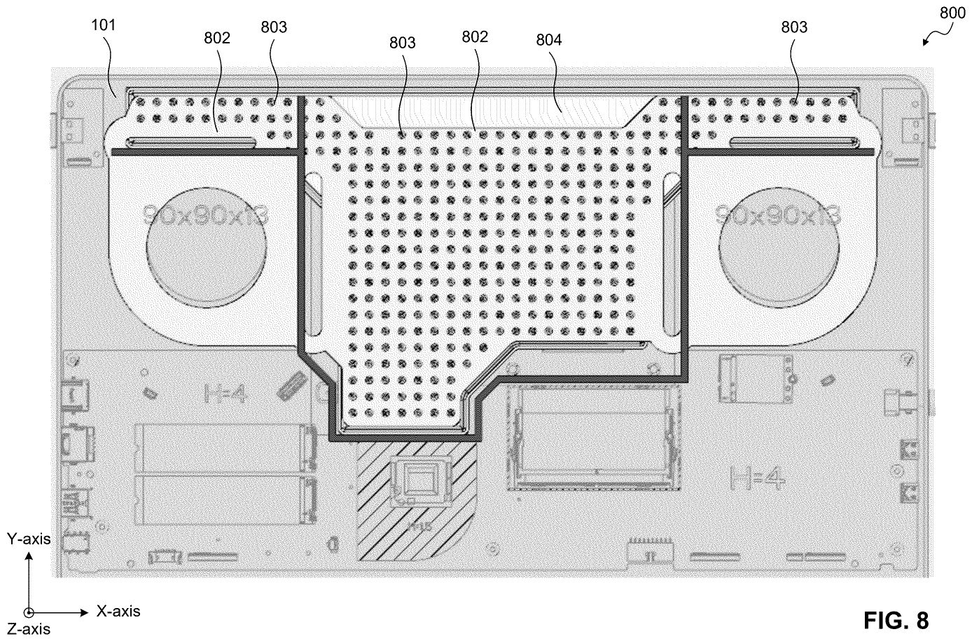

Referring to FIG. 8, a vapor chamber assembly 800 may be positioned above the board 101 to provide an alternative thermal management configuration. The vapor chamber assembly 800 may differ from the vapor chamber assembly 100 by omitting embossments. In this configuration, the embossments may be included on spreader layers rather than on the vapor chamber itself. This alternative configuration may provide enhanced thermal management capabilities while utilizing conventional vapor chamber designs in combination with embossed spreader components. In one or more configurations, the configurations of the vapor chamber assembly 100 and vapor chamber assembly 800 may be combined so that the vapor chamber and the spreaders(s) include embossments. The vapor chamber assembly 800, together with the spreader layers, may form a vapor chamber system configured for enhanced thermal management.

The vapor chamber assembly 800 may include an upper spreader 802 that forms a top layer of the thermal management structure. The upper spreader 802 may feature an array of embossments 803 distributed across the surface in a regular or random pattern. The embossments 803 may appear as small circular, cylindrical, or conical features arranged in rows and columns throughout a central region of the upper spreader 802. The embossments 803 may extend from the surface of the upper spreader 802 to create thermal connection points and enhanced surface area for heat transfer operations.

A vapor chamber 804 may be positioned beneath the upper spreader 802 and may be visible in a central area of the vapor chamber assembly 800. The vapor chamber 804 may feature conventional vapor chamber construction without embossments on the vapor chamber surfaces themselves. Instead, the thermal enhancement may be provided through the embossed features on the spreader layers that interface with the vapor chamber 804. The vapor chamber 804 may contain working fluid and facilitate phase-change heat transfer processes similar to conventional vapor chamber designs.

The vapor chamber assembly 800 may provide increased heat exchange surface area through the embossed features on the upper spreader 802. The embossments 803 may be thermally coupled to (e.g., in contact with, connected, fastened, soldered, brazed, welded, bonded, adhesively attached, mechanically fastened, etc.) the vapor chamber 804 to facilitate heat dissipation from heat sources positioned on the board 101. The thermal connection between the embossments 803 and the vapor chamber 804 may be achieved through direct contact, thermal interface materials, solder joints, brazing, welding, thermal adhesives, mechanical fasteners, or other attachment methods that provide efficient heat transfer pathways.

The vapor chamber assembly 800 may also include a lower spreader that features embossments on the lower surface, providing thermal connection points and structural features similar to those provided by the upper spreader 802. The embossments on the lower spreader may interface with the vapor chamber 804 from the bottom side, creating thermal pathways that supplement the heat transfer capabilities provided by the upper spreader 802. The combination of embossed spreaders on both the upper and lower sides of the vapor chamber 804 may enhance the overall thermal performance of the vapor chamber assembly 800.

The vapor chamber assembly 800 may be combined with features from the vapor chamber assembly 100 to create hybrid thermal management configurations. For example, embossed spreaders may be used together with a vapor chamber that also may include embossed features on the vapor chamber layers themselves. The modular nature of the embossed thermal management components may allow for customization based on specific thermal performance requirements, available space constraints, and manufacturing considerations. The combination of different embossment approaches may provide enhanced thermal management capabilities that exceed the performance of individual embossment configurations.

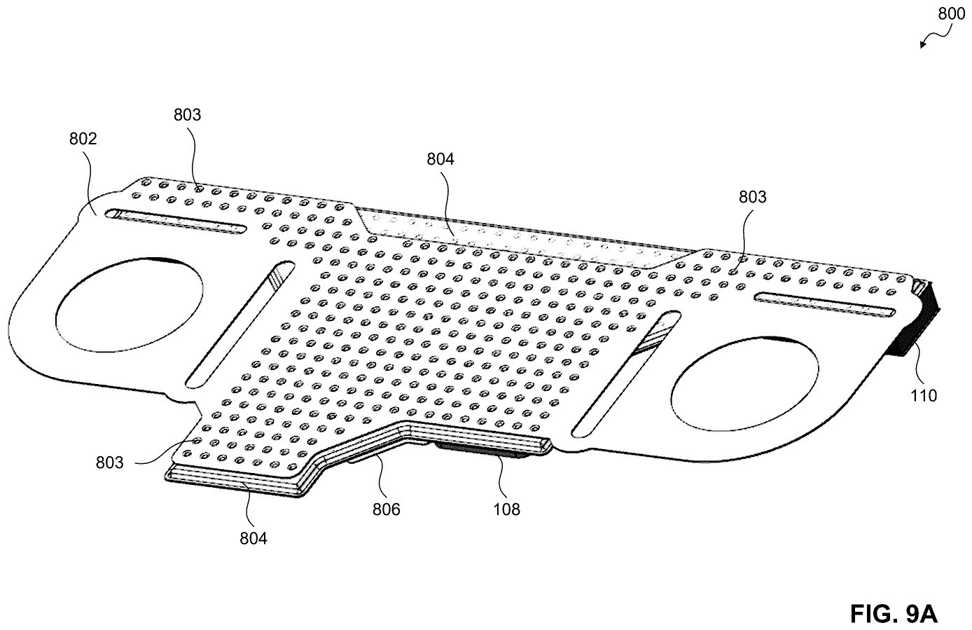

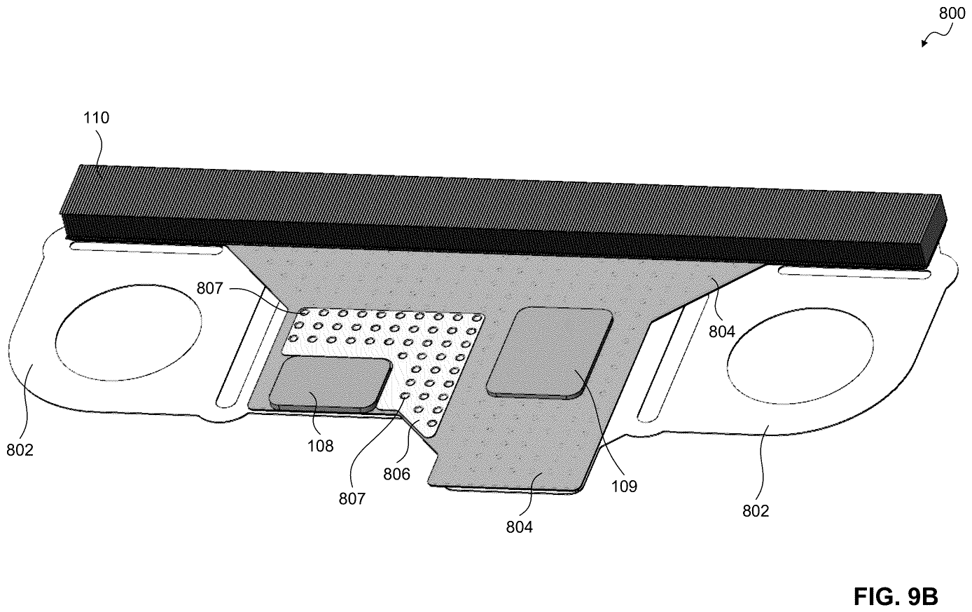

Referring to FIG. 9A, a top perspective view of the vapor chamber assembly 800 illustrates the layered configuration and thermal management components of the alternative embossed spreader design. The vapor chamber assembly 800 may include several components arranged in a layered configuration that provides enhanced thermal management capabilities through embossed spreader interfaces. The perspective view demonstrates the relationship between the spreader layers and the vapor chamber 804, showing how the embossed features create thermal connection points and structural interfaces within the thermal management system.

The upper spreader 802 may form the top layer of the vapor chamber assembly 800 and may feature multiple embossments 803 distributed across the surface in a regular pattern. The embossments 803 may appear as raised or dimpled features that extend from the upper spreader 802, creating thermal interface points that facilitate heat transfer between the upper spreader 802 and the vapor chamber 804. The embossments 803 may be arranged in rows and columns across the surface of the upper spreader 802, providing a structured array of thermal connection points that enhance the effective heat exchange surface area of the thermal management system.

The vapor chamber 804 may be positioned beneath the upper spreader 802 and may form the central component of the vapor chamber assembly 800. The vapor chamber 804 may include integrated features such as pedestals and connection points for thermal management operations. The vapor chamber 804 may utilize conventional vapor chamber construction without embossments on the vapor chamber surfaces, relying instead on the embossed features of the spreader layers to provide enhanced thermal performance characteristics.

A lower spreader 806 may be positioned beneath the vapor chamber 804, forming an additional layer of the thermal management structure. The lower spreader 806 may provide heat spreading capability and structural support for the vapor chamber assembly 800, working in conjunction with the upper spreader 802 to create a multi-layer thermal management configuration. The lower spreader 806 may be configured to interface with the vapor chamber 804 through thermal connection points and mechanical attachment methods.

The vapor chamber assembly 800 may also include the pedestal 108 and the heat spreader 110, which may be shown separated from the main vapor chamber assembly 800 to illustrate their relationship to the other components. The pedestal 108 may provide thermal interface connections to heat-generating components positioned on the board 101, while the heat spreader 110 may extend the effective cooling area beyond the immediate footprint of the vapor chamber assembly 800. The exploded view demonstrates how these components may be intended to be assembled together with the embossed spreader configuration.

The embossments 803 on the upper spreader 802 may provide thermal connection points and structural features that interface with the vapor chamber 804 to enhance heat dissipation and create enclosed channels for airflow. The thermal connection between the embossments 803 and the vapor chamber 804 may facilitate efficient heat transfer from heat sources to the vapor chamber 804, where the heat may be distributed through phase-change processes and dissipated through the enhanced surface area provided by the spreader layers.

With reference to FIG. 9B, a bottom perspective view of the vapor chamber assembly 800 shows the arrangement and relationship of components from the lower side of the thermal management structure. The bottom perspective view reveals additional thermal management features and demonstrates how the layered configuration creates comprehensive thermal pathways through the vapor chamber assembly 800. The view illustrates the positioning and interface characteristics of components that may be positioned on the lower side of the vapor chamber assembly 800.

The lower spreader 806 may feature an embossment 807 on the lower surface, which may provide thermal connection points and structural features for the vapor chamber assembly 800. The embossment 807 may extend from the surface of the lower spreader 806 to create thermal interface points that facilitate heat transfer between the lower spreader 806 and the vapor chamber 804. The embossment 807 may be configured similarly to the embossments 803 on the upper spreader 802, providing thermal coupling and structural support for the layered thermal management configuration.

The vapor chamber 804 may be positioned between the upper spreader 802 and the lower spreader 806, forming the central component of the layered thermal management structure. The vapor chamber 804 may interface with both the embossments 803 on the upper spreader 802 and the embossment 807 on the lower spreader 806, creating thermal pathways that facilitate heat transfer from both the upper and lower sides of the vapor chamber assembly 800. The dual-sided thermal interface configuration may enhance the overall thermal performance of the vapor chamber assembly 800 compared to single-sided thermal management approaches.

The vapor chamber assembly 800 may further include the pedestal 108 and the pedestal 109, which may be positioned to make thermal contact with heat sources positioned on the board 101. The pedestals 108, 109 may provide thermal interface connections between heat-generating electronic components and the vapor chamber assembly 800, facilitating efficient heat transfer from the heat sources to the thermal management structure. The heat spreader 110 may also be shown as part of the thermal management structure, providing extended surface area for heat dissipation beyond the immediate footprint of the vapor chamber assembly 800.

The bottom perspective view demonstrates how the components may be stacked and aligned to form the complete vapor chamber assembly 800. The embossments 803 on the upper spreader 802 and the embossment 807 on the lower spreader 806 may facilitate thermal conduction between the spreaders and the vapor chamber 804, creating efficient thermal pathways that enhance heat transfer performance. The layered configuration may allow for thermal management from both the upper and lower sides of the vapor chamber 804, providing comprehensive cooling capability for high-performance electronic applications.

The embossments 803 and 807 may create enclosed channels for airflow management within the vapor chamber assembly 800. The embossed features may establish spacing between the spreader layers and the vapor chamber 804, creating cavities that allow air to flow through the thermal management structure. The airflow through these enclosed channels may enhance heat dissipation by increasing heat transfer coefficients and providing additional cooling mechanisms that supplement the phase-change heat transfer occurring within the vapor chamber 804.

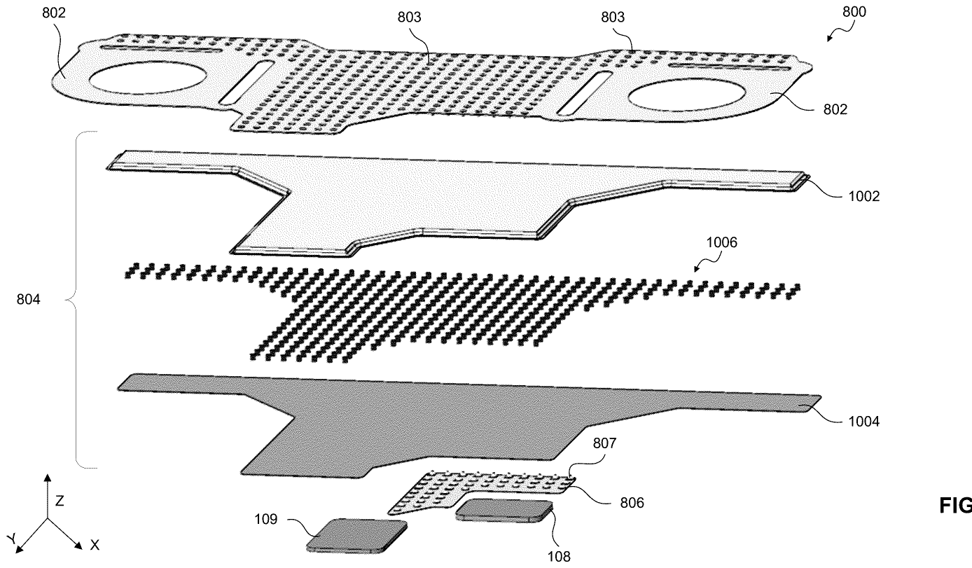

Referring to FIG. 10, an exploded view of the vapor chamber assembly 800 illustrates the detailed construction and assembly relationship of the various components within the thermal management structure. The exploded view demonstrates how multiple layers may be assembled together to form a complete vapor chamber assembly 800 with enhanced thermal management capabilities through embossed spreader interfaces. The exploded configuration reveals the internal structure and component alignment that facilitates efficient thermal transfer and structural integrity within the vapor chamber assembly 800.

The vapor chamber 804 may be formed by an upper vapor chamber layer 1002 and a lower vapor chamber layer 1004 that define the boundaries of the vapor chamber structure. The upper vapor chamber layer 1002 may form the upper boundary of the vapor zone within the vapor chamber 804, providing containment for working fluid and facilitating phase-change heat transfer processes. The lower vapor chamber layer 1004 may form the lower boundary of the vapor zone, working in conjunction with the upper vapor chamber layer 1002 to create a sealed environment for thermal management operations.

A support pillar 1006 may extend through the vapor chamber 804 to provide structural support and thermal conduction paths between the upper vapor chamber layer 1002 and the lower vapor chamber layer 1004. The support pillar 1006 may maintain the structural integrity of the vapor chamber 804 while facilitating heat transfer within the assembly. In some cases, multiple support pillars 1006 may be distributed throughout the vapor chamber 804 to provide adequate structural support while allowing for working fluid circulation within the vapor zone.

The upper spreader 802 may be positioned at the top of the vapor chamber assembly 800 and may feature the embossments 803 projecting downward from the surface. The embossments 803 may be intentionally aligned with the support pillars 1006 within the vapor chamber layers to provide structural enhancement and optimized thermal pathways. The alignment between the embossments 803 and the support pillars 1006 may create coordinated load transfer paths that distribute mechanical stresses while maintaining efficient thermal conduction through the vapor chamber assembly 800.

The lower spreader 806 may be positioned beneath the vapor chamber 804 and may feature the embossments 807 on the surface. The embossments 807 on the lower spreader 806 may also be aligned with the support pillars 1006 within the vapor chamber layers, creating structural continuity through the entire vapor chamber assembly 800. The alignment of the embossments 807 with the support pillars 1006 may provide additional surface area for heat dissipation and create thermal connection points that enhance heat transfer between the lower spreader 806 and the vapor chamber 804.

The structural alignment between the embossments 803, 807 and the support pillars 1006 may provide manufacturing advantages by creating consistent geometric relationships that may be accommodated by existing thermal module supplier assembly lines. The aligned configuration may allow for standard fabrication processes and assembly techniques that are already established in thermal management manufacturing operations. The vapor chamber assembly 800 may be manufactured using conventional assembly line equipment and processes, providing better manufacturability and cost effectiveness compared to more complex thermal management configurations.

The pedestals 108 and 109 may be positioned at the bottom of the vapor chamber assembly 800 to serve as mounting or contact interfaces with heat-generating components. The pedestal 108 and the pedestal 109 may be positioned to make thermal contact with electronic devices such as processors, graphics processing units, memory modules, voltage regulators, power management integrated circuits, system-on-chip devices, or other heat-generating components positioned on the board 101. The thermal interface provided by the pedestals 108, 109 may facilitate efficient heat transfer from heat sources to the vapor chamber assembly 800, where the heat may be distributed through the aligned thermal pathways created by the embossments 803, 807 and the support pillars 1006.

The exploded view demonstrates how the components may stack vertically and align with one another during assembly operations. The embossments 803 and 807 on the upper spreader 802 and the lower spreader 806, respectively, may be positioned to align with the support pillars 1006 within the vapor chamber layers, creating efficient thermal conduction paths throughout the vapor chamber assembly 800. The aligned configuration may facilitate assembly processes by providing consistent reference points and geometric relationships that may be maintained during manufacturing operations using existing assembly line infrastructure.

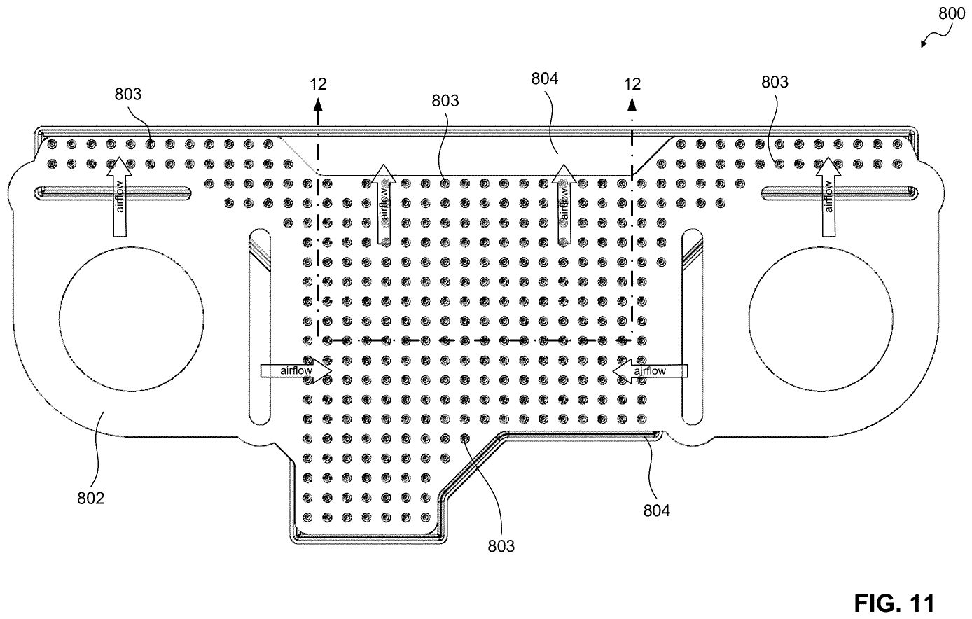

Referring to FIG. 11, a top view of the vapor chamber assembly 800 illustrates the overall arrangement and component configuration of the thermal management structure. The vapor chamber assembly 800 may be positioned to provide enhanced thermal management capabilities through the embossed spreader configuration according to the disclosure. The top view demonstrates the spatial relationship between the primary thermal management components and provides reference information for detailed cross-sectional analysis of the vapor chamber assembly 800.

The upper spreader 802 may be visible as the top layer of the vapor chamber assembly 800, forming the primary surface that interfaces with the surrounding thermal environment. The upper spreader 802 may extend across the surface area of the vapor chamber assembly 800, providing heat spreading capability and structural support for the thermal management structure. The upper spreader 802 may be configured to facilitate heat transfer from the underlying vapor chamber 804 to the surrounding environment through enhanced surface area and thermal conduction pathways.

The vapor chamber 804 may be positioned beneath the upper spreader 802 and may be visible in the central region of the vapor chamber assembly 800. The vapor chamber 804 may form the primary thermal management component that facilitates phase-change heat transfer processes during operation of the thermal management system. The vapor chamber 804 may be configured to contain working fluid and provide thermal distribution capabilities that supplement the heat spreading functions provided by the upper spreader 802.

The embossments 803 may be distributed across the surface of the upper spreader 802 in a regular pattern that creates thermal connection points and enhanced surface area for heat transfer operations. The embossments 803 may be arranged to optimize thermal transfer characteristics while providing structural interfaces between the upper spreader 802 and the vapor chamber 804. The distribution pattern of the embossments 803 may be selected to accommodate the thermal performance requirements and structural considerations of the vapor chamber assembly 800.

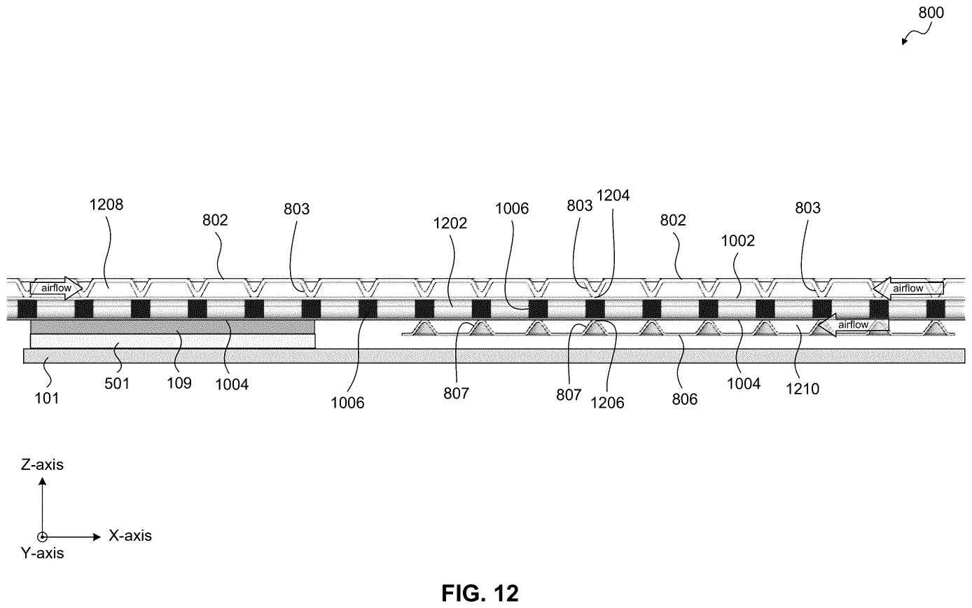

The cross-sectional view illustrated in FIG. 12 is taken along the cross-section line 12-12 shown in dashed lines through the vapor chamber assembly 800. The cross-section line 12-12 shows the plane along which a sectional view may be taken to reveal internal details and component relationships within the thermal management structure. The cross-section line 12-12 is be positioned to intersect the primary thermal management components, including the upper spreader 802, the vapor chamber 804, and associated structural elements. The cross-sectional reference line may provide a guide for detailed analysis of the internal configuration and thermal pathways within the vapor chamber assembly 800.

The cross-section line 12-12 may be oriented to reveal the layered construction and thermal interface characteristics of the vapor chamber assembly 800. The sectional plane indicated by the cross-section 12 may intersect the embossments 803 and other thermal management features, providing visibility of the internal structure and component relationships that facilitate enhanced thermal performance. The cross-sectional reference may correspond to detailed views that illustrate the thermal conduction pathways and structural support mechanisms within the vapor chamber assembly 800.

The vapor chamber assembly 800 may provide enhanced heat dissipation capability by increasing the effective heat exchange surface area through the addition of the upper spreader 802 with the embossments 803. The thermal management configuration shown in the top view may demonstrate how the embossed spreader approach creates additional thermal pathways while maintaining compatibility with conventional vapor chamber designs. The arrangement of components visible in the top view may illustrate the spatial efficiency and thermal optimization characteristics of the vapor chamber assembly 800 configuration.

Referring to FIG. 12, a cross-sectional view of the vapor chamber assembly 800 mounted on the board 101 reveals the internal structure and thermal interface characteristics of the embossed spreader configuration. The vapor chamber assembly 800 may include the upper spreader 802 and the lower spreader 806, with the embossments 803 on the upper spreader 802 and the embossments 807 on the lower spreader 806. Between the upper spreader 802 and the lower spreader 806 may be a vapor chamber structure comprising the upper vapor chamber layer 1002 and the lower vapor chamber layer 1004.

A vapor zone 1202 may be defined in an interior region between the upper vapor chamber layer 1002 and the lower vapor chamber layer 1004, where phase-change heat transfer occurs during operation of the vapor chamber assembly 800. The vapor zone 1202 may contain working fluid that undergoes phase transitions to facilitate heat transfer within the vapor chamber structure. The vapor zone 1202 may be sealed between the upper vapor chamber layer 1002 and the lower vapor chamber layer 1004, maintaining the working fluid in a controlled environment for thermal management operations.

The vapor chamber assembly 800 may include multiple support pillars 501 and 1006 positioned within the vapor zone 1202 to provide structural support and thermal connectivity between the upper vapor chamber layer 1002 and the lower vapor chamber layer 1004. The support pillars 501 and 1006 may extend through the vapor zone 1202, connecting the upper and lower vapor chamber layers to maintain structural integrity of the vapor chamber assembly 800. The support pillars 501 and 1006 may be configured to facilitate heat transfer within the assembly while allowing for working fluid circulation within the vapor zone 1202.

The embossments 803 on the upper spreader 802 may extend downward and make thermal contact with the upper vapor chamber layer 1002 at a connection point 1204. The connection point 1204 may facilitate thermal transfer between the upper spreader 802 and the upper vapor chamber layer 1002, creating an efficient thermal pathway for heat dissipation. The connection point 1204 may be formed through direct contact, thermal interface materials, or mechanical attachment methods that provide thermal conductivity between the embossments 803 and the upper vapor chamber layer 1002.

Similarly, the embossments 807 on the lower spreader 806 may extend upward and make thermal contact with the lower vapor chamber layer 1004 at a connection point 1206. The connection point 1206 may facilitate thermal transfer between the lower spreader 806 and the lower vapor chamber layer 1004, creating thermal pathways that supplement the heat transfer capabilities provided by the upper spreader 802. The connection point 1206 may be configured to provide efficient thermal conduction between the embossments 807 and the lower vapor chamber layer 1004.

The connection points 1204 and 1206 may be solder joints that provide both mechanical attachment and thermal connectivity between the spreader layers and the vapor chamber layers. The solder joints may be formed using conventional soldering processes that create metallurgical bonds between the embossed features and the vapor chamber surfaces. The solder joints may provide reliable thermal and mechanical interfaces that maintain performance characteristics during thermal cycling and operational stresses.

The embossments 803 and 807 may create enclosed air flow channels within the vapor chamber assembly 800. A cavity 1208 may be formed between the upper spreader 802 and the upper vapor chamber layer 1002, creating an enclosed channel for airflow management. The cavity 1208 may extend across portions of the upper surface of the vapor chamber assembly 800, providing space for air to flow and make thermal contact with the surfaces of the upper spreader 802 and the upper vapor chamber layer 1002.

A cavity 1210 may be formed between the lower spreader 806 and the lower vapor chamber layer 1004, creating an additional enclosed channel for airflow. The cavity 1210 may extend across portions of the lower surface of the vapor chamber assembly 800, providing space for air circulation and thermal contact with the surfaces of the lower spreader 806 and the lower vapor chamber layer 1004. The cavities 1208 and 1210 may work together to create a comprehensive airflow management system that enhances heat dissipation performance of the vapor chamber assembly 800.

The spreader layers may be attached to the vapor chamber main body through soldering after the sealing and vacuuming process of the vapor chamber structure. The post-seal soldering process may allow the vapor chamber to be manufactured using conventional vapor chamber fabrication techniques, with the embossed spreader layers added as a subsequent assembly step. The post-seal attachment process may provide manufacturing advantages by separating the vapor chamber sealing operations from the spreader attachment operations, allowing for better process control and quality assurance.

The vapor chamber assembly 800 may be implemented with minimal height (z-direction) requirements that accommodate the enhanced thermal management capabilities while maintaining compatibility with existing system designs. The minimal height requirement for the vapor chamber assembly 800 may be, for example, 0.5-5 mm, such as 1-3 mm. For example, the height may be 1.3 mm, including a 0.8-1.5 mm gap (such as 1-1.1 mm) for airflow to pass through the cavities 1208 and 1210 with lower flow resistance, and a 0.1-0.5 mm spreader thickness (such as 0.2-0.3 mm) for effective heat spreading. Other dimensional configurations may be selected based on system requirements and thermal performance objectives. The gap may provide sufficient space for air circulation through the enclosed channels while maintaining structural integrity of the vapor chamber assembly 800.

The spreader thickness may be configured so as to provide adequate thermal spreading capability while minimizing the overall height impact of the enhanced thermal management configuration. The minimal height requirements may allow the vapor chamber assembly 800 to be integrated into mainstream gaming laptops and other electronic devices with system height constraints, where the main bottleneck may be fan height rather than the board area stack. The dimensional requirements may be compatible with existing thermal management system designs while providing enhanced cooling capabilities.

The upper spreader 802 and the lower spreader 806 may be made of copper, aluminum, silver, nickel, titanium, stainless steel, copper alloys, aluminum alloys, graphite, carbon composites, metal matrix composites, or other thermally conductive materials for effective heat spreading. Copper spreaders may provide higher thermal conductivity characteristics, facilitating efficient heat transfer from the connection points 1204 and 1206 to the extended surface areas of the spreader layers. Aluminum spreaders may provide weight reduction benefits while maintaining adequate thermal spreading performance for many applications. The material selection for the spreader layers may be based on thermal performance requirements, weight considerations, and cost constraints of the specific application.

The pedestal 109 may be positioned below the lower spreader 806, providing thermal contact between the board 101 and the vapor chamber assembly 800. The pedestal 109 may facilitate heat transfer from heat-generating components positioned on the board 101 to the vapor chamber assembly 800, where the heat may be distributed through the thermal pathways created by the embossments 803 and 807 and the connection points 1204 and 1206. The embossments 803 and 807 may be distributed across the spreader surfaces to enhance heat exchange surface area and facilitate airflow through the cavities 1208 and 1210, thereby improving thermal dissipation performance of the vapor chamber assembly 800.

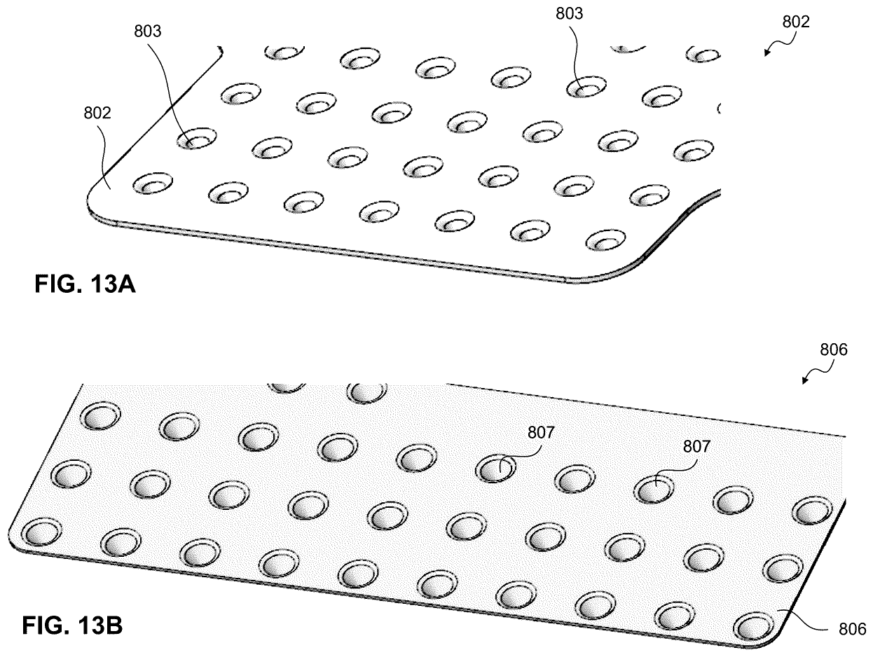

Referring to FIGS. 13A and 13B, detailed views of the spreader components illustrate the surface configuration and embossment distribution characteristics of the upper spreader 802 and the lower spreader 806. The spreader components may provide enhanced thermal interface capabilities through strategically positioned embossed features that facilitate thermal connection and mechanical attachment to the vapor chamber structure. The detailed views demonstrate the geometric arrangement and pattern distribution of the embossments that create thermal pathways and structural interfaces within the vapor chamber assembly 800.

With reference to FIG. 13A, a top view of the upper spreader 802 shows the surface configuration and embossment arrangement of the upper thermal management component. The upper spreader 802 may have an irregular, curved perimeter shape that may be configured to accommodate specific system layout requirements and thermal management constraints. The curved perimeter may allow the upper spreader 802 to fit within available space constraints while maximizing the effective heat spreading area for thermal management operations.

Multiple embossments 803 may be arranged in a pattern across the upper spreader 802, with each embossment 803 appearing as a circular or oval feature. The embossments 803 may be distributed across the surface area of the upper spreader 802 in a configuration that optimizes thermal transfer characteristics while accommodating manufacturing constraints and structural requirements. The pattern of the embossments 803 may be selected to provide adequate thermal connection points while maintaining the structural integrity of the upper spreader 802 during thermal cycling and operational stresses.

The embossments 803 may provide thermal connection points and structural features for heat transfer and mechanical attachment to an underlying vapor chamber structure. The embossments 803 may extend from the surface of the upper spreader 802 to create thermal interface points that facilitate efficient heat transfer between the upper spreader 802 and the vapor chamber 804. The thermal connection provided by the embossments 803 may supplement the heat spreading capabilities of the upper spreader 802 by creating localized thermal pathways that enhance heat transfer performance.

The distribution pattern of the embossments 803 may be configured to correspond with structural features within the vapor chamber assembly 800, such as support pillars or thermal interface components. The alignment between the embossments 803 and internal vapor chamber features may create coordinated thermal pathways that optimize heat transfer while providing structural support for the layered thermal management configuration. The pattern arrangement may also facilitate manufacturing processes by providing consistent geometric relationships that may be accommodated by standard fabrication techniques.

With reference to FIG. 13B, a bottom view of the lower spreader 806 illustrates the surface configuration and embossment distribution of the lower thermal management component. The lower spreader 806 may have a generally rectangular shape with rounded corners that may be configured to provide structural support and thermal spreading capability for the vapor chamber assembly 800. The rectangular configuration may allow the lower spreader 806 to interface with standard mounting configurations while providing adequate surface area for thermal management operations.

Multiple embossments 807 may be arranged in a pattern across the lower spreader 806, with each embossment 807 appearing as a circular feature with a raised rim. The embossments 807 may be distributed across the surface of the lower spreader 806 in a configuration that provides thermal connection points and structural features for heat transfer and mechanical attachment to an underlying vapor chamber structure. The raised rim configuration of the embossments 807 may provide enhanced thermal contact area and mechanical attachment characteristics compared to other embossment geometries.

The embossments 807 may provide thermal connection points and structural features for heat transfer and mechanical attachment to the vapor chamber structure. The embossments 807 may extend from the surface of the lower spreader 806 to create thermal interface points that facilitate heat transfer between the lower spreader 806 and the vapor chamber 804. The thermal interface provided by the embossments 807 may work in conjunction with the embossments 803 on the upper spreader 802 to create comprehensive thermal pathways through the vapor chamber assembly 800.

The embossments 807 on the lower spreader 806 may be aligned with corresponding features in the vapor chamber assembly 800 to facilitate efficient heat conduction and structural integrity. The alignment between the embossments 807 and internal vapor chamber components may create coordinated load transfer paths that distribute mechanical stresses while maintaining efficient thermal conduction through the vapor chamber assembly 800. The aligned configuration may also provide manufacturing advantages by creating consistent geometric relationships that may be maintained during assembly operations.

The pattern and distribution of the embossments 803 and 807 on the respective spreader components may be configured to optimize thermal performance while accommodating manufacturing constraints and system integration requirements. The embossment patterns may be selected based on thermal modeling results, structural analysis considerations, and manufacturing process capabilities. The distribution of the embossments 803 and 807 may also be configured to accommodate different thermal load distributions and heat source configurations within the electronic system.

The embossments 803 and 807 may create enhanced surface area for thermal contact between the spreader layers and the vapor chamber structure. The embossed features may increase the effective thermal interface area compared to planar contact configurations, providing improved thermal transfer characteristics and reduced thermal resistance between the spreader components and the vapor chamber 804. The enhanced thermal interface may contribute to improved overall thermal performance of the vapor chamber assembly 800 compared to conventional thermal management configurations.

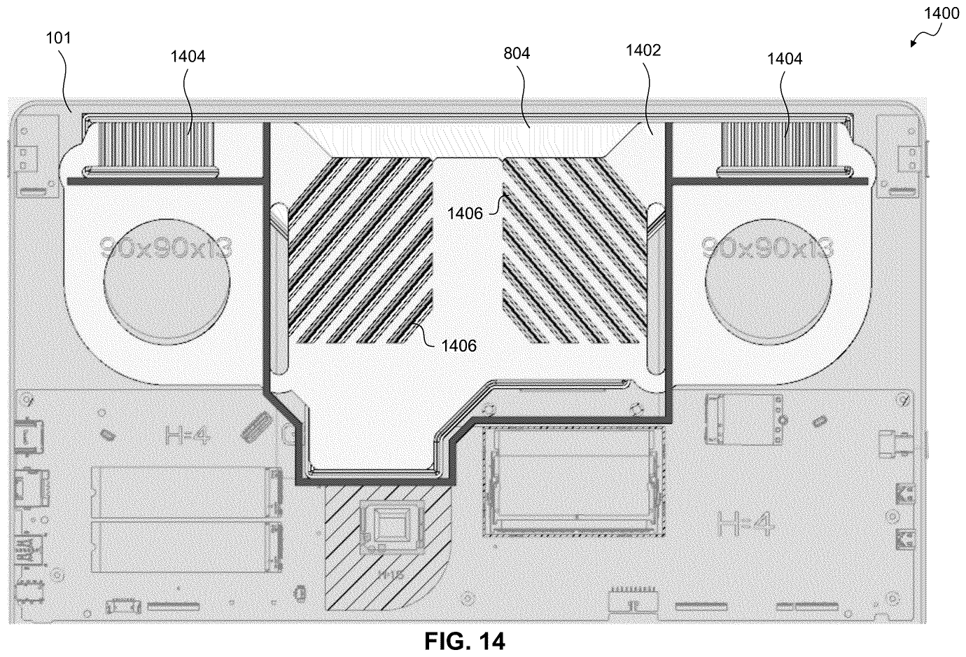

Referring to FIG. 14, a vapor chamber assembly 1400 may be positioned above the board 101 to provide an alternative thermal management configuration that utilizes elongated embossed features rather than discrete circular embossments. The vapor chamber assembly 1400 may include the vapor chamber 804 as a central component, with an upper heat spreader 1402 disposed on an upper surface of the vapor chamber 804. The upper heat spreader 1402 may feature embossed wave structures 1404 and 1406 that extend across portions of the vapor chamber 804, creating elongated thermal interface features that differ from the circular or conical embossments according to the disclosure. The embossed wave structures 1404 and 1406 may be elongated wave structures (also referred to as wave-like protrusions, corrugated features, or undulating structures) that extend across portions of the vapor chamber 804.

The embossed wave structures 1404 may be located on opposite sides of the vapor chamber assembly 1400, positioned near left and right edges of the thermal management structure. Each embossed wave structure 1404 may comprise a series of parallel diagonal protrusions or indentations that form a wave-like pattern across the surface of the upper heat spreader 1402. The diagonal orientation of the embossed wave structures 1404 may provide structural reinforcement while facilitating thermal transfer between the vapor chamber 804 and the upper heat spreader 1402.

The embossed wave structures 1406 may be positioned in a central region of the vapor chamber assembly 1400, also featuring diagonal line patterns that create enclosed channels for airflow management. The embossed wave structures 1406 may extend across the central portion of the upper heat spreader 1402, providing additional thermal contact area and surface enhancement compared to discrete embossment configurations. The diagonal orientation of the embossed wave structures 1406 may facilitate directional airflow guidance while maintaining thermal connectivity between the upper heat spreader 1402 and the vapor chamber 804.

The vapor chamber 804 may extend beneath the upper heat spreader 1402 and may provide a primary heat dissipation structure for the vapor chamber assembly 1400. The vapor chamber 804 may utilize conventional vapor chamber construction similar to the configurations according to the disclosure, containing working fluid and facilitating phase-change heat transfer processes during thermal management operations. The interface between the vapor chamber 804 and the upper heat spreader 1402 may be enhanced through the thermal contact provided by the embossed wave structures 1404 and 1406.

The embossed wave structures 1404 and 1406 may create additional surface area for heat exchange compared to planar thermal interface configurations. The wave-like patterns may form ducting features that guide airflow through the vapor chamber assembly 1400, directing air movement in specific directions to optimize cooling performance. The elongated nature of the embossed wave structures 1404 and 1406 may provide continuous thermal pathways that extend across larger surface areas compared to discrete circular embossments, potentially enhancing heat spreading characteristics within the upper heat spreader 1402.

The diagonal orientation of the embossed wave patterns may provide structural reinforcement for the upper heat spreader 1402 while facilitating thermal transfer between the vapor chamber 804 and the upper heat spreader 1402. The wave structures may create corrugated patterns that increase the effective surface area available for thermal contact while maintaining structural integrity of the thermal management assembly. The embossed wave structures 1404 and 1406 may be configured to accommodate thermal expansion and mechanical loads during operation while providing enhanced thermal interface characteristics compared to conventional planar thermal management configurations.

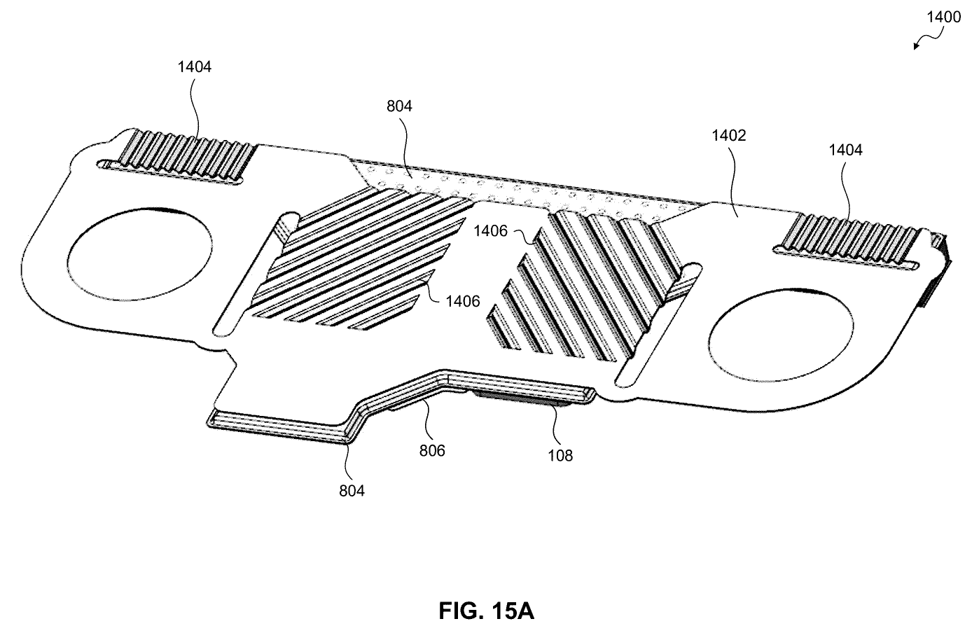

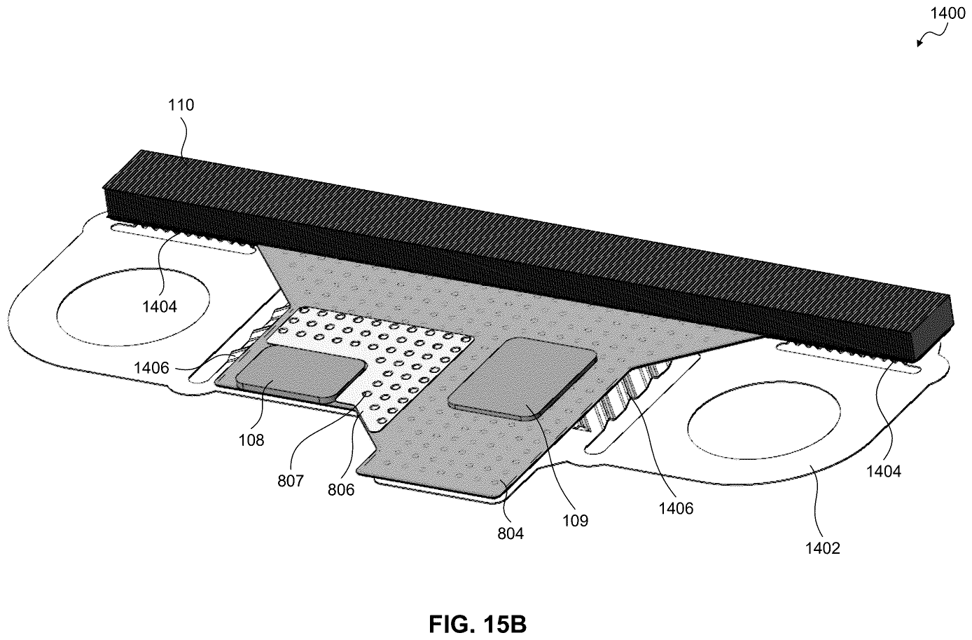

Referring to FIG. 15A, a top perspective view of the vapor chamber assembly 1400 illustrates the relationship between thermal management components and demonstrates how the embossed wave structures may be integrated with conventional vapor chamber designs. The vapor chamber assembly 1400 may include the upper heat spreader 1402 positioned at the top of the assembly, the vapor chamber 804 in a middle section, and the lower spreader 806 at the bottom. The perspective view shows the three-dimensional configuration of the thermal management structure and the spatial arrangement of the embossed features that enhance thermal performance.

The upper heat spreader 1402 may feature the embossed wave structures 1404 on the surface, which may be arranged in multiple locations across the spreader. The embossed wave structures 1404 may be positioned to align with the vapor chamber 804 when assembled, creating thermal connection points that facilitate heat transfer between the upper heat spreader 1402 and the vapor chamber 804. The wave structures may extend across portions of the upper heat spreader 1402 surface, providing elongated thermal pathways that differ from discrete circular embossment configurations.

Additional embossed wave structures 1406 may also be present on the upper heat spreader 1402, positioned in different regions to provide comprehensive thermal interface coverage. The embossed wave structures 1406 may be configured to create thermal connection points and enhanced surface area for heat transfer operations. The combination of the embossed wave structures 1404 and 1406 may provide multiple thermal pathways that distribute heat across the surface of the upper heat spreader 1402 while maintaining structural integrity of the thermal management assembly.

The pedestal 108 may interface with the vapor chamber 804 to facilitate thermal transfer from a heat source positioned on the board. The pedestal 108 may be configured to make direct thermal contact with electronic devices or processors, providing an efficient thermal pathway for heat transfer from heat-generating components to the vapor chamber assembly 1400. The thermal interface provided by the pedestal 108 may work in conjunction with the embossed wave structures to create comprehensive thermal management capabilities.

The lower spreader 806 may provide structural support and additional heat spreading capability at the bottom of the vapor chamber assembly 1400. The lower spreader 806 may be configured to interface with the vapor chamber 804 through thermal connection points and mechanical attachment methods. The lower spreader 806 may work in conjunction with the upper heat spreader 1402 to create a multi-layer thermal management configuration that enhances heat dissipation performance compared to single-sided thermal management approaches.

The vapor chamber assembly 1400 may be configured to enhance thermal dissipation by increasing the effective heat exchange surface area through the embossed wave structures 1404 and 1406. The wave structures may create enclosed channels for airflow while maintaining thermal connection to the vapor chamber 804. The enclosed channels may direct airflow across the embossed surfaces and thermal interface areas, increasing heat transfer coefficients and improving overall cooling performance of the vapor chamber assembly 1400.

With reference to FIG. 15B, a bottom perspective view of the vapor chamber assembly 1400 shows the relationship between multiple thermal management components from the lower side of the thermal management structure. The bottom perspective view reveals additional thermal interface features and demonstrates how the layered configuration creates comprehensive thermal pathways through the vapor chamber assembly 1400. The view illustrates the positioning and interface characteristics of components that may be positioned on the lower side of the vapor chamber assembly 1400.

The upper heat spreader 1402 may be positioned at the top of the vapor chamber assembly 1400 and may feature the embossed wave structures 1404 and 1406 on the surface. The embossed wave structures 1404 and 1406 may create channels for airflow and increase the effective heat exchange surface area of the thermal management system. The wave structures may be visible from the bottom perspective view, demonstrating the three-dimensional configuration of the elongated embossed features that enhance thermal performance.

The vapor chamber 804 may be positioned beneath the upper heat spreader 1402 and may form the central thermal transfer component of the vapor chamber assembly 1400. The vapor chamber 804 may interface with the embossed wave structures 1404 and 1406 on the upper heat spreader 1402, creating thermal pathways that facilitate heat transfer from heat sources to the thermal management structure. The vapor chamber 804 may utilize conventional vapor chamber construction while benefiting from the enhanced thermal interface provided by the embossed wave structures.

The lower spreader 806 may be positioned beneath the vapor chamber 804 and may include the embossments 807 on the surface. The embossments 807 may provide thermal connection points to the vapor chamber 804, creating thermal pathways that supplement the heat transfer capabilities provided by the upper heat spreader 1402. The embossments 807 may be configured similarly to the embossments according to the disclosure, providing thermal coupling and structural support for the layered thermal management configuration.

The vapor chamber assembly 1400 may incorporate the pedestal 108 with an attached heat spreader 110, and a separate pedestal 109, both of which may provide thermal interface connections to heat-generating components. The pedestal 108 and the pedestal 109 may be positioned to make thermal contact with electronic devices positioned on the board, facilitating efficient heat transfer from heat sources to the vapor chamber assembly 1400. The heat spreader 110 may extend the effective cooling area beyond the immediate footprint of the vapor chamber assembly 1400, providing additional thermal dissipation capability.

The bottom perspective view demonstrates how the components may stack together to form a complete thermal solution with the spreaders enclosing the vapor chamber 804 while maintaining air passages for enhanced cooling performance. The embossed wave structures 1404 and 1406 on the upper heat spreader 1402 may create channels for airflow management, while the embossments 807 on the lower spreader 806 may provide thermal connection points that enhance heat transfer between the lower spreader 806 and the vapor chamber 804. The layered configuration may allow for thermal management from both the upper and lower sides of the vapor chamber 804, providing comprehensive cooling capability for high-performance electronic applications.

The different embossment configurations described in the vapor chamber assembly 1400 may be interchanged and combined in various aspects based on spacing and dimensional constraints of the electronic devices. The embossed wave structures 1404 and 1406 may be used in combination with discrete circular embossments, or the wave structures may be applied to both the upper heat spreader 1402 and the lower spreader 806 depending on available space and thermal performance requirements. The modular nature of the embossed thermal management components may allow for customization based on specific application requirements and system integration constraints.

Referring to FIG. 16, a top view of the vapor chamber assembly 1400 illustrates the overall configuration and component arrangement of the thermal management structure with elongated embossed features. The vapor chamber assembly 1400 may include the vapor chamber 804 positioned centrally within the thermal management structure, with the upper heat spreader 1402 attached to a top surface of the vapor chamber 804. The top view demonstrates the spatial relationship between the primary thermal management components and provides reference information for detailed cross-sectional analysis of the vapor chamber assembly 1400.

The upper heat spreader 1402 may feature the embossed wave structures 1404, creating a series of parallel ridges and channels across portions of the thermal management surface. The embossed wave structures 1404 may be oriented diagonally across the upper heat spreader 1402, creating angled channels that facilitate airflow through the vapor chamber assembly 1400. The diagonal orientation may provide directional airflow guidance that enhances heat transfer characteristics compared to conventional planar thermal interface configurations.

The embossed wave structures 1406 may extend downward to contact the top surface of the vapor chamber 804, forming corresponding parallel ridges and channels that complement the embossed wave structures 1404. The embossed wave structures 1406 may be thermally coupled to (e.g., in contact with, connected, fastened, soldered, etc.) the vapor chamber 804 through contact points that facilitate efficient heat transfer between the upper heat spreader 1402 and the vapor chamber 804. The thermal connection provided by the embossed wave structures 1406 may create continuous thermal pathways that extend across larger surface areas compared to discrete circular embossment configurations.

The diagonal orientation of the embossed wave structures 1404 and 1406 may create angled channels (also referred to as elongated channels, extended channels, or linear airflow passages) that facilitate airflow through the vapor chamber assembly 1400. The angled channels may direct air movement in specific directions to optimize cooling performance and heat dissipation characteristics. The diagonal configuration may provide enhanced airflow guidance compared to straight or perpendicular channel orientations, allowing for more efficient air movement through the thermal management structure while maintaining thermal connectivity between the spreader and vapor chamber components.

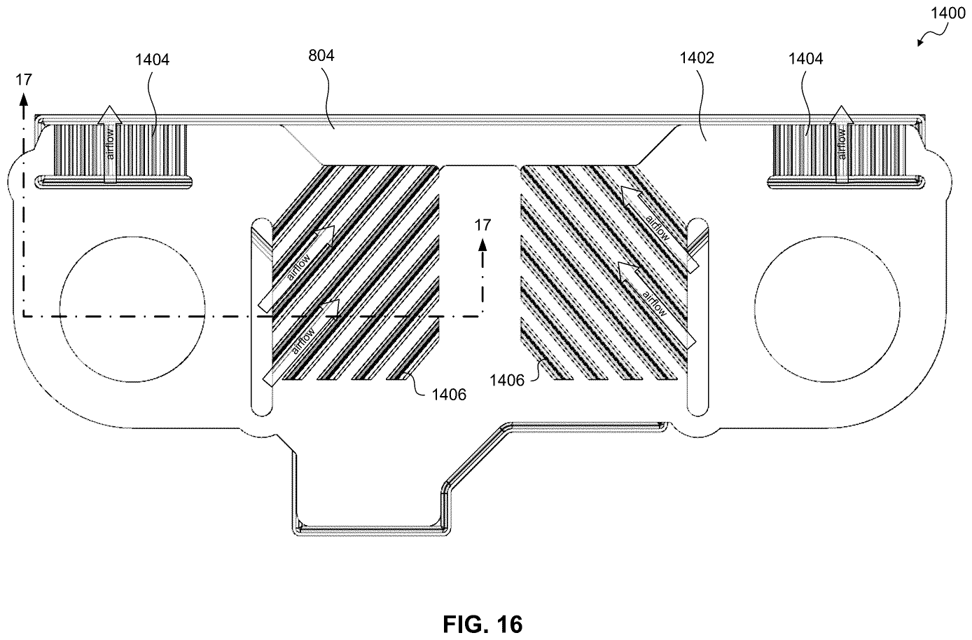

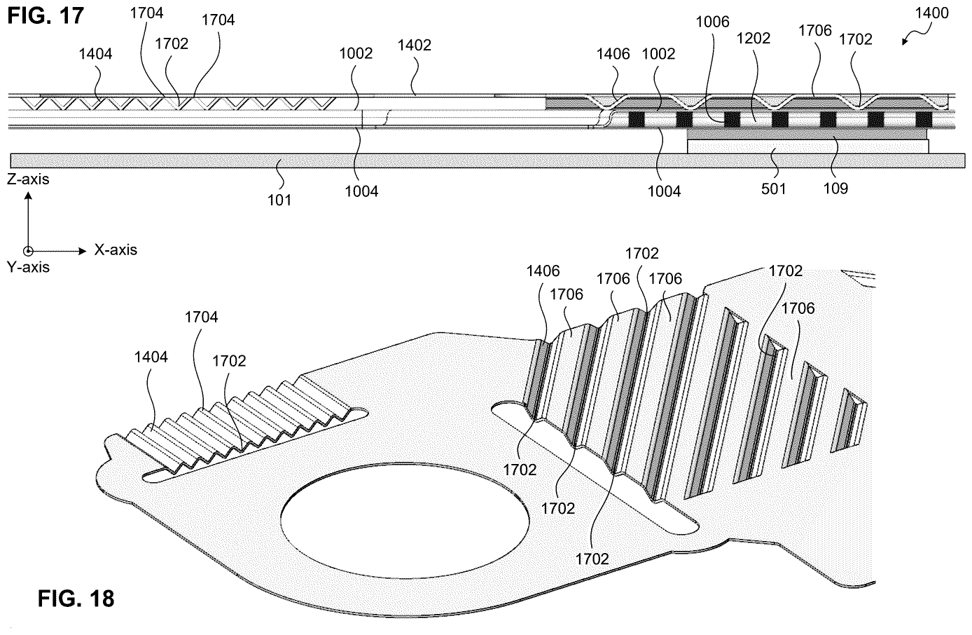

The cross-sectional view illustrated in FIG. 17 is taken along the cross-section line 17-17 shown in dashed lines in FIG. 16 through the vapor chamber assembly 1400. The cross-section line 17-17 shows the plane along which a sectional view may be taken to reveal internal details and component relationships within the thermal management structure. The cross-section line 17-17 may be positioned to intersect the primary thermal management components, including the upper heat spreader 1402, the vapor chamber 804, and the embossed wave structures 1404 and 1406. The cross-sectional reference line may provide a guide for detailed analysis of the internal configuration and thermal pathways within the vapor chamber assembly 1400.

The embossed wave structures 1404 and 1406 may increase the effective heat exchange surface area by creating extended surfaces that interact with airflow passing through the channels formed between the ridges. The wave-like configuration may maximize the contact area between the heat spreader surfaces and cooling air, enhancing thermal dissipation by providing increased surface area for convective heat transfer. The enhanced thermal interface may contribute to improved overall thermal performance of the vapor chamber assembly 1400 compared to conventional thermal management configurations.

The embossed features may serve as ducting features for guiding airflow toward an exhaust location within the thermal management system. The embossed wave structures 1404 and 1406 may be configured to direct airflow in specific directions, creating guided air movement that enhances heat transfer characteristics while facilitating efficient air circulation through the vapor chamber assembly 1400. The ducting functionality provided by the embossed features may supplement the thermal spreading capabilities of the upper heat spreader 1402 by optimizing airflow patterns for enhanced cooling performance.

The embossed features may be replaced with groove line features that serve as ducting features for guiding airflow toward the exhaust. The groove line features may create concave channels that direct air movement across the surface of the upper heat spreader 1402, providing airflow guidance functionality while maintaining thermal connectivity to the vapor chamber 804. The groove line configuration may provide alternative geometric characteristics that accommodate different airflow requirements and thermal performance objectives within the vapor chamber assembly 1400.

Referring to FIGS. 17 and 18, cross-sectional and perspective views of the vapor chamber assembly 1400 illustrate the detailed geometry and structural characteristics of the embossed wave structures. The vapor chamber assembly 1400 may be positioned above the board 101 and may comprise the upper vapor chamber layer 1002 and the lower vapor chamber layer 1004, which together define the vapor zone 1202 between them. The support pillars 501 and 1006 may extend within the vapor zone 1202 to provide structural support between the upper vapor chamber layer 1002 and the lower vapor chamber layer 1004 while facilitating heat transfer within the assembly.

The upper heat spreader 1402 may be positioned above the upper vapor chamber layer 1002 and may include the embossed wave structures 1404 formed to contact the upper surface of the upper vapor chamber layer 1002. The embossed wave structures 1404 may create a series of undulating features that extend upward from the interface with the upper vapor chamber layer 1002, forming a corrugated pattern that increases the effective surface area available for thermal contact and heat dissipation. The wave-like configuration may provide enhanced thermal interface characteristics compared to planar contact configurations.

The embossed wave structures 1404 may include a lower portion 1702 forming a valley of the wave structure and an upper portion 1704 forming a peak of the wave structure. The lower portion 1702 may represent the recessed areas of the wave pattern that may be positioned closer to the upper vapor chamber layer 1002, while the upper portion 1704 may represent the elevated areas of the wave pattern that extend further from the upper vapor chamber layer 1002. The alternating arrangement of the lower portions 1702 and the upper portions 1704 may create the undulating wave pattern that characterizes the embossed wave structures 1404.

Similarly, the embossed wave structures 1406 may be formed to contact the surface of the upper vapor chamber layer 1002, creating undulating features that extend in a different orientation or pattern compared to the embossed wave structures 1404. The embossed wave structures 1406 may include the lower portions 1702 and the upper portions 1704 arranged in a wave-like configuration that provides thermal connectivity and enhanced surface area for heat transfer operations. The embossed wave structures 1406 may be positioned in different regions of the upper heat spreader 1402 to provide comprehensive thermal interface coverage.

A planar portion 1706 may connect the lower portions 1702 and the upper portions 1704, forming sloped surfaces of the wave pattern. The planar portion 1706 may provide transitional surfaces between the valleys and peaks of the wave structures, creating continuous thermal pathways that extend across the embossed features. The planar portions 1706 may facilitate heat transfer along the wave structures while providing structural continuity within the embossed wave patterns.

The perspective view shown in FIG. 18 may provide a three-dimensional configuration of the embossed wave structures, illustrating how the lower portions 1702, the upper portions 1704, and the planar portions 1706 combine to form the corrugated pattern. The embossed wave structures 1404 and 1406 may each comprise alternating lower portions 1702 and upper portions 1704, with the planar portions 1706 connecting these features to form sloped surfaces of the wave pattern. The three-dimensional configuration may demonstrate how the wave structures create enhanced surface area and thermal pathways within the vapor chamber assembly 1400.

The embossed wave structures may create enclosed channels that facilitate airflow across the surfaces of the vapor chamber assembly 1400, thereby increasing the effective heat exchange surface area for enhanced thermal dissipation. The channels formed between adjacent wave features may allow air to flow through the thermal management structure, making thermal contact with the extended surfaces created by the lower portions 1702, the upper portions 1704, and the planar portions 1706. The enclosed channels may direct airflow in specific patterns that optimize heat transfer characteristics while maintaining thermal connectivity between the upper heat spreader 1402 and the vapor chamber structure.

The vapor chamber assembly 1400 may achieve up to 2× increased surface area for heat exchanging, depending on the actual design implementation. The embossed wave structures 1404 and 1406 may significantly increase the effective thermal interface area compared to conventional planar thermal management configurations. The wave-like patterns may create extended surfaces that provide additional contact area for thermal transfer operations, potentially doubling the available surface area for heat exchange compared to flat interface configurations. The increased surface area capability may enhance thermal dissipation performance while maintaining compatibility with existing system designs and manufacturing processes.

The pedestal 109 may be positioned below the lower vapor chamber layer 1004, providing thermal contact with the board 101 and facilitating heat transfer from heat-generating components to the vapor chamber assembly 1400. The thermal pathway created by the pedestal 109 may work in conjunction with the enhanced surface area provided by the embossed wave structures to create comprehensive thermal management capabilities. The combination of the increased thermal interface area and the efficient heat input pathways may provide enhanced cooling performance for high-performance electronic applications.

The support pillars 501 and 1006 may facilitate heat transfer within the vapor chamber assembly 1400 while allowing for working fluid circulation within the vapor zone 1202. The support pillars may be configured to provide structural integrity while accommodating the enhanced thermal interface characteristics provided by the embossed wave structures. The combination of the internal support structure and the external embossed features may create a comprehensive thermal management system that provides both structural stability and enhanced thermal performance compared to conventional vapor chamber designs.

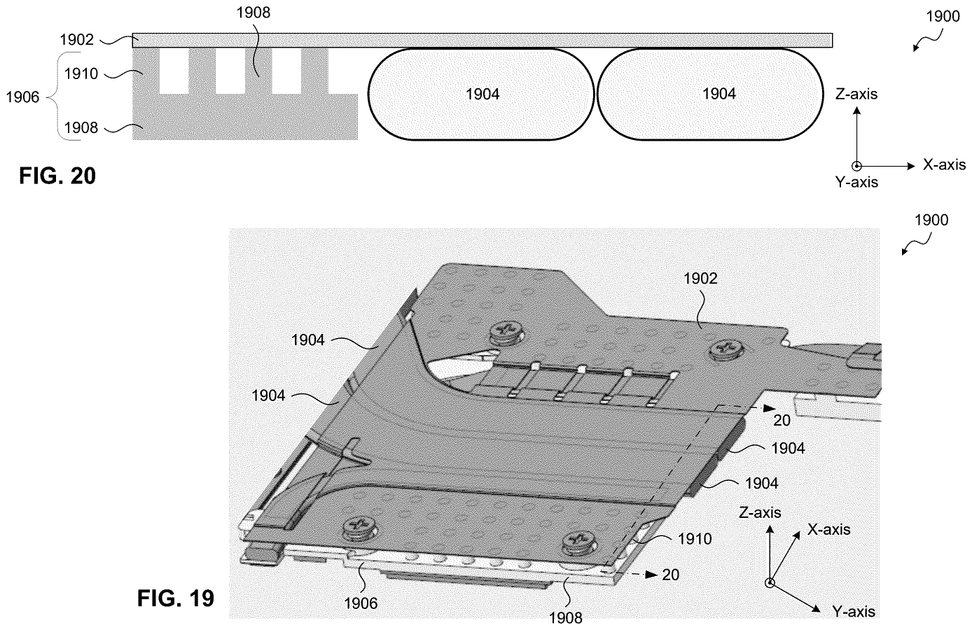

Referring to FIGS. 19 and 20, a heat pipe system 1900 provide a thermal management configuration that utilizes heat pipes integrated with spreader layers to enhance cooling performance as an alternative to vapor chamber designs. The heat pipe system 1900 may offer different thermal management and/or dimensional characteristics compared to the vapor chamber assemblies according to the disclosure, providing flexibility in thermal solution selection based on specific application requirements, space constraints, and performance objectives. The heat pipe system 1900 may be particularly suitable for applications where heat pipe technology may be preferred over vapor chamber technology due to manufacturing considerations, cost constraints, or thermal performance characteristics.

The heat pipe system 1900 may include an upper spreader 1902 positioned above multiple heat pipes 1904 to provide enhanced heat spreading capability and thermal interface characteristics. The upper spreader 1902 may be configured similarly to the spreader components according to the disclosure, providing extended surface area for heat dissipation and thermal distribution. The upper spreader 1902 may create an enclosed channel above other components of the heat pipe system 1900, facilitating airflow management and enhanced thermal performance compared to conventional heat pipe configurations without spreader layers.

Multiple heat pipes 1904 may be integrated into the heat pipe system 1900, extending laterally to provide thermal conduction pathways for heat transfer operations. The heat pipes 1904 may contain working fluid and utilize phase-change heat transfer processes similar to vapor chamber technology, but may be configured in elongated tubular structures that provide directional heat transfer capabilities. The heat pipes 1904 may be positioned to facilitate heat transfer from heat sources to heat dissipation areas, providing thermal pathways that distribute heat across the thermal management structure.

The heat pipes 1904 may be thermally coupled to other components of the heat pipe system 1900 to facilitate heat transfer operations. The thermal coupling may be achieved through direct contact, thermal interface materials, or mechanical attachment methods that provide efficient thermal conduction between the heat pipes 1904 and adjacent thermal management components. The thermal coupling may allow the heat pipes 1904 to work in conjunction with the upper spreader 1902 and other system components to create comprehensive thermal management capabilities.

A die cast 1906 may provide structural support and thermal interface characteristics for the heat pipe system 1900. The die cast 1906 may be positioned adjacent to the heat pipes 1904 and may be configured to facilitate thermal transfer between the heat pipes 1904 and other components of the thermal management structure. The die cast 1906 may be formed using conventional die casting processes that create integrated thermal and structural components with enhanced manufacturing efficiency compared to assembled thermal management configurations.

The die cast 1906 may be formed by a base 1908 that provides a foundation structure for the heat pipe system 1900. The base 1908 may be configured to interface with heat-generating components positioned on the board and may provide thermal contact surfaces that facilitate heat transfer from heat sources to the heat pipe system 1900. The base 1908 may be integrated with the die cast 1906 to create a unified structural and thermal component that simplifies assembly operations while providing enhanced thermal performance characteristics.

Multiple pillars 1910 may extend between the upper spreader 1902 and the base 1908, providing mechanical support and thermal connection points within the heat pipe system 1900. The pillars 1910 may be configured to maintain structural integrity of the heat pipe system 1900 while facilitating thermal transfer between the upper spreader 1902 and the base 1908. The pillars 1910 may be positioned to accommodate the heat pipes 1904 and other thermal management components while providing adequate structural support for the layered thermal management configuration.

The pillars 1910 may provide thermal conduction pathways that supplement the heat transfer capabilities provided by the heat pipes 1904. The pillars 1910 may be configured to conduct heat between the upper spreader 1902 and the base 1908, creating additional thermal pathways that enhance the overall thermal performance of the heat pipe system 1900. The thermal conduction provided by the pillars 1910 may work in conjunction with the phase-change heat transfer occurring within the heat pipes 1904 to create comprehensive thermal management capabilities.

With reference to FIG. 19, a top view of the heat pipe system 1900 illustrates the overall arrangement and component configuration. The heat pipe system 1900 may be positioned to provide thermal management capabilities that differ from vapor chamber configurations while utilizing similar spreader layer concepts to enhance thermal performance. The top view demonstrates the spatial relationship between the primary thermal management components and provides reference information for detailed cross-sectional analysis of the heat pipe system 1900.

With reference to FIG. 20, a cross-sectional view of the heat pipe system 1900 reveals the internal structure and component relationships within the alternative thermal management configuration. The cross-sectional view may be taken along the dashed cross-section line 20-20 shown in FIG. 19, providing detailed visibility of the layered construction and thermal interface characteristics of the heat pipe system 1900. The cross-sectional view demonstrates how the various components may be arranged and connected to create enhanced thermal management capabilities using heat pipe technology. The cross-sectional view illustrated in FIG. 20 is taken along the cross-section line 20-20 shown in dashed lines in FIG. 19 through the heat pipe system 1900, showing the plane along which a sectional view may be taken to reveal internal details and component relationships within the thermal management structure.

The upper spreader 1902 may increase the effective heat exchange surface area by creating an enclosed channel above the base 1908. The enclosed channel may facilitate airflow management and thermal dissipation similar to the enclosed channels described according to the disclosure. The upper spreader 1902 may work in conjunction with the heat pipes 1904 to create enhanced thermal management capabilities that exceed the performance of conventional heat pipe configurations without spreader layers. In one or more aspects, the upper spreader 1902 may include one or more embossed features similar to the embossments (e.g., protrusions, projections, wave-structures, etc.) discussed above, such as the embossments 803 of spreader 802 described with reference to FIGS. 8-18. Additionally, or alternatively, the heat pipe system 1900 may include one or more other spreaders (e.g., a bottom spreader beneath the heat pipe(s) 1904 and/or die cast 1906. Additionally, or alternatively, the heat pipe(s) 1904 may include one or more embossed features similar to the embossments (e.g., protrusions, projections, wave-structures, etc.) discussed above, which may similarly create one or cavities/channels for increased airflow between the heat pipe(s) 1904 and the spreader 1902.

The heat pipe system 1900 may provide an alternative thermal management configuration that utilizes heat pipes 1904 in combination with spreader layers to enhance cooling performance. The combination of heat pipe technology with spreader layer concepts may provide thermal management characteristics that differ from vapor chamber approaches while maintaining enhanced surface area and thermal performance benefits. The heat pipe system 1900 may be selected for applications where heat pipe technology may be preferred over vapor chamber technology due to specific thermal requirements, manufacturing considerations, or system integration constraints.

The heat pipe system 1900 may be implemented with similar dimensional requirements and manufacturing processes as the vapor chamber assemblies according to the disclosure. The upper spreader 1902 and the base 1908 may be configured to provide minimal height (e.g., in the Z-direction) impact while enhancing thermal performance through increased surface area and improved airflow management. The heat pipe system 1900 may be compatible with existing thermal management system designs while providing alternative thermal technology options for different application requirements.

The thermal management assemblies described herein may operate through coordinated interactions between multiple thermal transfer mechanisms that work together to provide enhanced cooling performance for electronic devices. The thermal management process may begin when heat-generating components positioned on electronic boards create thermal loads that may be transferred through thermal interface pathways to the vapor chamber assemblies. The heat transfer process may involve multiple stages of thermal conduction, phase-change heat transfer, and convective cooling that work in combination to dissipate heat from electronic systems.

Heat sources such as processors, graphics processing units, or other electronic components may generate thermal energy during operation that may be conducted through pedestals to the vapor chamber assemblies. The pedestals may provide direct thermal contact interfaces that facilitate efficient heat transfer from heat sources to the thermal management structures. The thermal energy may be conducted through the pedestal materials to the vapor chamber layers, where the heat may be distributed across larger surface areas through thermal spreading and phase-change heat transfer processes.

The vapor zones within the vapor chamber structures may contain working fluid that undergoes phase transitions to facilitate heat transfer across the vapor chamber assemblies. The working fluid may absorb thermal energy from heated surfaces within the vapor chambers, causing the fluid to vaporize and create vapor that may travel through the vapor zones to cooler regions of the vapor chambers. The vapor may condense on cooler surfaces within the vapor zones, releasing thermal energy and creating condensate that may return to heated regions through capillary action or gravitational forces. The phase-change heat transfer mechanism may provide efficient thermal distribution that spreads heat across the entire surface area of the vapor chamber structures.

The embossed features positioned on vapor chamber layers and spreader components may facilitate thermal conduction pathways that supplement the phase-change heat transfer occurring within the vapor zones. The embossed features may create direct thermal contact points between vapor chamber layers and spreader components, allowing thermal energy to be conducted through metallic pathways that bypass the phase-change processes. The thermal conduction through embossed features may provide additional thermal transfer mechanisms that enhance the overall thermal performance of the vapor chamber assemblies beyond the capabilities provided by phase-change heat transfer alone.

Support pillars positioned within vapor zones may provide both structural support and thermal conduction pathways that maintain the integrity of vapor chamber assemblies while facilitating heat transfer operations. The support pillars may extend between vapor chamber layers to distribute mechanical loads and prevent structural deformation during thermal cycling and operational stresses. The support pillars may also conduct thermal energy between vapor chamber layers, creating thermal pathways that supplement the phase-change heat transfer and embossed feature thermal conduction mechanisms. The dual functionality of the support pillars may optimize both thermal and mechanical performance characteristics within the vapor chamber assemblies.

The spreader layers positioned above and below vapor chamber structures may receive thermal energy through the embossed features and thermal conduction pathways, distributing the heat across extended surface areas that increase the effective thermal interface area available for heat dissipation. The spreader layers may conduct thermal energy away from the thermal connection points created by embossed features, spreading the heat across larger surface areas that facilitate enhanced thermal transfer to surrounding air. The thermal spreading provided by the spreader layers may reduce thermal gradients and hot spots while increasing the effective cooling area beyond the immediate footprint of the vapor chamber structures.

The embossed features may create enclosed airflow channels between spreader layers and vapor chamber surfaces that facilitate convective heat transfer through directed air movement. Air may enter the enclosed channels and travel across the embossed surfaces, making thermal contact with the enhanced surface area created by the embossed features. The air movement through the enclosed channels may accelerate due to the channel geometry, increasing heat transfer coefficients and improving convective cooling performance. The heated air may exit the enclosed channels and be replaced by cooler air, creating continuous airflow that enhances heat dissipation from the thermal management assemblies.

The various embossment configurations described herein may be combined in different ways to optimize thermal performance for specific applications and system requirements. Circular or conical embossments may be used together with wave structure embossments within the same thermal management assembly to provide different thermal transfer characteristics in different regions of the thermal management structure. The circular embossments may provide localized thermal connection points that align with specific thermal interface requirements, while wave structure embossments may provide elongated thermal pathways that facilitate directional heat spreading and airflow guidance.

Embossed spreader configurations may be combined with embossed vapor chamber layer configurations to create hybrid thermal management assemblies that utilize enhanced thermal interfaces on both spreader components and vapor chamber components. The combination of embossed spreaders with embossed vapor chamber layers may provide multiple levels of thermal enhancement that exceed the performance capabilities of individual embossment approaches. The hybrid configurations may create comprehensive thermal pathways that optimize heat transfer through multiple mechanisms while maintaining structural integrity and manufacturing feasibility.

Different embossment configurations may be applied to upper and lower spreaders within the same thermal management assembly to accommodate different thermal requirements and space constraints on each side of the vapor chamber structures. The upper spreader may utilize wave structure embossments that facilitate directional airflow guidance, while the lower spreader may utilize circular embossments that provide localized thermal connection points for specific heat source interfaces. The asymmetric embossment configuration may allow for customized thermal management that addresses different thermal loads and cooling requirements on each side of the vapor chamber assembly.

The modular nature of the embossed thermal management components may allow for thermal solution customization based on specific electronic device requirements, available space constraints, and thermal performance objectives. The embossment patterns, geometries, and distributions may be selected and combined to create thermal management assemblies that address specific thermal challenges while maintaining compatibility with existing manufacturing processes and system integration requirements. The flexibility provided by the various embossment configurations may enable thermal management solutions that may be tailored to different electronic applications while utilizing common thermal management principles and manufacturing approaches.

The thermal management assemblies may achieve enhanced cooling performance through the coordinated interaction of phase-change heat transfer, thermal conduction through embossed features and support structures, thermal spreading through spreader layers, and convective cooling through enclosed airflow channels. The combination of these thermal transfer mechanisms may provide comprehensive thermal management capabilities that exceed the performance of conventional thermal management approaches while maintaining compatibility with existing electronic system designs and manufacturing processes.

The vapor chamber assemblies described herein may provide substantial advantages over conventional thermal management approaches, particularly for high-performance electronic applications that demand enhanced cooling capabilities. The disclosed thermal management solutions may address limitations of existing cooling technologies while maintaining practical implementation characteristics that facilitate adoption in commercial electronic systems. The enhanced thermal performance characteristics may enable electronic devices to operate at higher power levels while maintaining acceptable temperature limits and user experience standards.

The vapor chamber assemblies may achieve enhanced cooling capability for high-performance gaming laptops through the combination of increased effective heat exchange surface area and improved thermal conduction pathways. The embossed features and spreader layer configurations may create thermal management systems that exceed the cooling performance of conventional vapor chamber designs by providing additional thermal transfer mechanisms and enhanced surface area for heat dissipation. The enhanced cooling capability may enable gaming laptops to accommodate higher-power processors and graphics processing units while maintaining thermal performance within acceptable operating limits.

The vapor chamber assemblies may be specifically designed for HX/S based high-end gaming laptop designs without height constraints, targeting 350W combined CPU and GPU cooling capability. The 350W thermal management target may represent a substantial increase over conventional gaming laptop cooling capabilities, which may typically achieve 280W to 300W cooling performance using conventional air cooling or external liquid cooling approaches. The enhanced thermal management capability may enable gaming laptops to accommodate next-generation processors and graphics processing units that generate higher thermal loads while maintaining acceptable performance characteristics.

The increased effective heat exchange surface area provided by the embossed features and spreader layers may contribute to enhanced thermal dissipation performance compared to conventional planar thermal interface configurations. The embossed features may create additional surface area that increases the surface area (e.g., doubles the surface area) of conventional thermal management approaches, depending on the specific embossment configuration and distribution pattern. The increased surface area may facilitate enhanced heat transfer to surrounding air through convective cooling mechanisms while providing additional thermal conduction pathways through the thermal management structure.

The vapor chamber assemblies may provide reduced thermal resistance compared to conventional thermal management approaches through the elimination of thermal interface bottlenecks and the creation of multiple parallel thermal pathways. The embossed features may create direct thermal conduction paths that bypass thermal interface materials and reduce the overall thermal resistance between heat sources and heat dissipation surfaces. The reduced thermal resistance may facilitate more efficient heat transfer from electronic components to the thermal management structure, resulting in lower operating temperatures for heat-generating components.

Lower junction temperatures and skin temperatures may be achieved through the enhanced thermal dissipation capabilities provided by the vapor chamber assemblies. The junction temperatures of electronic components may be reduced through more efficient heat transfer from the component surfaces to the thermal management structure, while skin temperatures may be reduced through enhanced heat dissipation from the thermal management surfaces to the surrounding environment. The temperature reductions may improve electronic component reliability and user experience by maintaining acceptable surface temperatures during high-performance operation.

The vapor chamber assemblies may provide improved airflow management through the creation of enclosed channels that direct air movement across enhanced thermal surfaces. The enclosed channels formed by the spreader layers and embossed features may accelerate airflow and increase heat transfer coefficients compared to conventional thermal management configurations that rely on external airflow across planar surfaces. The improved airflow management may enhance convective cooling performance while reducing the acoustic requirements for cooling fans by improving the efficiency of air movement through the thermal management structure.

Better structural rigidity may be achieved through the layered construction and support structure configurations of the vapor chamber assemblies. The spreader layers may provide additional structural support that reduces deflection and mechanical stress within the thermal management structure, while the embossed features and support pillars may distribute mechanical loads across multiple load paths. The enhanced structural rigidity may improve the reliability and durability of the thermal management assemblies while maintaining thermal performance characteristics during mechanical stress and thermal cycling conditions.

The vapor chamber assemblies may address limitations of conventional thermal management approaches that may be constrained by insufficient heat exchanger surface area, limited thermal conduction pathways, and inadequate airflow management. Conventional thermal management solutions may rely on external heat exchangers and additional cooling fans to achieve high thermal performance, resulting in increased system complexity, cost, and acoustic levels. The disclosed vapor chamber assemblies may provide enhanced thermal performance through internal thermal management enhancements that may reduce the reliance on external cooling components while achieving superior thermal dissipation capabilities.

The thermal management solutions may maintain practical manufacturability characteristics that facilitate adoption in commercial electronic systems. The vapor chamber assemblies may be manufactured using conventional vapor chamber fabrication techniques with spreader layer attachment as a subsequent assembly step, allowing thermal module suppliers to utilize existing manufacturing infrastructure and assembly processes. The post-seal attachment process for spreader layers may provide manufacturing advantages by separating vapor chamber sealing operations from spreader attachment operations, enabling better process control and quality assurance compared to integrated manufacturing approaches.

Cost effectiveness may be maintained through the utilization of conventional materials and manufacturing processes that may be readily implemented by existing thermal management suppliers. The spreader layers may be fabricated using standard copper or aluminum materials and conventional forming processes, while the embossed features may be created using established fabrication techniques such as stamping, forming, or machining. The manufacturing approach may allow thermal management suppliers to produce the enhanced vapor chamber assemblies using existing equipment and processes, minimizing the capital investment requirements for implementation.

The height of the vapor chamber assemblies may facilitate integration into existing electronic system designs without substantial mechanical modifications. For example, a 1-3 mm height addition may be compatible with conventional electronic devices, such as mainstream gaming laptop designs, where fan height rather than board area stack may represent the primary dimensional constraint. The dimensional compatibility may allow the enhanced thermal management capabilities to be implemented in existing system architectures while providing substantial thermal performance improvements over conventional thermal management approaches.

The vapor chamber assemblies may provide thermal management solutions that enable electronic systems to achieve higher performance levels while maintaining acceptable acoustic characteristics and user experience standards. The enhanced thermal dissipation capabilities may allow electronic components to operate at higher power levels without requiring increased fan speeds or external cooling systems that may compromise user experience through increased noise levels or system complexity. The thermal management enhancements may facilitate the development of high-performance electronic systems that maintain acceptable acoustic and thermal characteristics for consumer applications.

### EXAMPLES

The following examples pertain to various techniques of the present disclosure.

An example (e.g. example 1) is a vapor chamber system, comprising: a vapor chamber; and a heat spreader disposed on the vapor chamber and including a surface facing the vapor chamber, wherein the surface includes one or more protrusions extending from the surface towards the vapor chamber, the one or more protrusions being configured to thermally couple the heat spreader to the vapor chamber.

Another example (e.g. example 2) relates to a previously-described example (e.g. example 1), wherein the one or more protrusions define one or more cavities between the heat spreader and the vapor chamber, the one or more cavities being configured to direct airflow between the heat spreader and the vapor chamber.

Another example (e.g. example 3) relates to a previously-described example (e.g. one or more of examples 1-2), wherein the one or more protrusions are conical protrusions.

Another example (e.g. example 4) relates to a previously-described example (e.g. one or more of examples 1-3), wherein the one or more protrusions comprise elongated wave structures extending across at least a portion of the surface of the heat spreader.

Another example (e.g. example 5) relates to a previously-described example (e.g. example 4), wherein the elongated wave structures include alternating upper portions and lower portions forming a corrugated pattern.

Another example (e.g. example 6) relates to a previously-described example (e.g. one or more of examples 4-5), wherein the elongated wave structures define elongated channels between the heat spreader and the vapor chamber, the elongated channels being configured to direct airflow between the heat spreader and the vapor chamber.

Another example (e.g. example 7) relates to a previously-described example (e.g. e.g. one or more of examples 1-6), wherein the vapor chamber includes one or more support members extending between an upper vapor chamber layer and a lower vapor chamber layer, the one or more protrusions being aligned with the one or more support members.

Another example (e.g. example 8) relates to a previously-described example (e.g. one or more of examples 1-7), wherein the one or more protrusions are fastened to the vapor chamber.

Another example (e.g. example 9) relates to a previously-described example (e.g. one or more of examples 1-8), wherein the one or more protrusions are soldered to the vapor chamber.

An example (e.g. example 10) is a vapor chamber, comprising: a first layer; a second layer spaced from the first layer in a first direction to define a vapor zone between the first and the second layers; and one or more support members disposed in the vapor chamber and between the first and the second layers, wherein the second layer comprises one or more protrusions extending from a surface of the second layer in the first direction and configured to interface with at least a portion of the one or more support members.

Another example (e.g. example 11) relates to a previously-described example (e.g. example 10), wherein the first layer comprises one or more protrusions extending from a surface of the first layer in a second direction opposite the first direction.

Another example (e.g. example 12) relates to a previously-described example (e.g. example 11), wherein the one or more protrusions of the first layer are configured to interface with at least a portion of the one or more support members.

Another example (e.g. example 13) relates to a previously-described example (e.g. example 11), further comprising a second support member of the one or more support members, wherein the one or more protrusions of the first layer are configured to interface with at least a portion of the second support member.

Another example (e.g. example 14) relates to a previously-described example (e.g. example 11), wherein at least one protrusion of the one or more protrusions of the second layer is aligned with and disposed opposite to at least one corresponding protrusion of the one or more protrusions of the first layer.

Another example (e.g. example 15) relates to a previously-described example (e.g. example 11), wherein at least one of the one or more support members is a dual-sided support member having a first portion interfacing with a protrusion of the one or more protrusions of the first layer and a second portion interfacing with a protrusion of the one or more protrusions of the second layer.

Another example (e.g. example 16) relates to a previously-described example (e.g. one or more of examples 10-15), wherein the one or more protrusions are conical protrusions.

Another example (e.g. example 17) relates to a previously-described example (e.g. one or more of examples 10-16), wherein the one or more protrusions define corresponding cavities configured to receive at least the portion of the one or more support members.

Another example (e.g. example 18) relates to a previously-described example (e.g. one or more of examples 10-17), further comprising a heat spreader disposed on and spaced from the surface of the second layer, wherein the one or more protrusions are configured to thermally couple the second layer to the heat spreader.

Another example (e.g. example 19) relates to a previously-described example (e.g. example 18), wherein the one or more protrusions define one or more cavities between the heat spreader and the second layer, the one or more cavities being configured to direct airflow between the second layer and the heat spreader.

Another example (e.g. example 20) relates to a previously-described example (e.g. one or more of examples 10-19), wherein the one or more support members are configured to thermally couple the first and second layers together.

Another example (e.g. example 21) relates to a previously-described example (e.g. one or more of examples 10-20), wherein the one or more support members comprise a cylindrical body and at least one conical portion.

An example (e.g. example 22) is a vapor chamber system, comprising: a vapor chamber including one or more protrusions extending from a first surface of the vapor chamber; and a heat spreader disposed on the vapor chamber and including a second surface facing the first surface of the vapor chamber, wherein the second surface includes one or more protrusions extending from the second surface towards the first surface of the vapor chamber, the one or more protrusions of the heat spreader and/or the one or more protrusions of the vapor chamber being configured to thermally couple the heat spreader to the vapor chamber.

An example (e.g. example 23) is a phase-change heat transferring means system, comprising: a phase-change heat transferring means; and a heat spreading means disposed on the phase-change heat transferring means and including a surface facing the phase-change heat transferring means, wherein the surface includes one or more protrusions extending from the surface towards the phase-change heat transferring means, the one or more protrusions being configured to thermally couple the heat spreading means to the phase-change heat transferring means.

Another example (e.g. example 24) relates to a previously-described example (e.g. example 23), wherein the one or more protrusions define one or more cavities between the heat spreading means and the phase-change heat transferring means, the one or more cavities being configured to direct airflow between the heat spreading means and the phase-change heat transferring means.

Another example (e.g. example 25) relates to a previously-described example (e.g. one or more of examples 23-24), wherein the one or more protrusions are conical protrusions.

Another example (e.g. example 26) relates to a previously-described example (e.g. one or more of examples 23-25), wherein the one or more protrusions comprise elongated wave structures extending across at least a portion of the surface of the heat spreading means.

Another example (e.g. example 27) relates to a previously-described example (e.g. example 26), wherein the elongated wave structures include alternating upper portions and lower portions forming a corrugated pattern.

Another example (e.g. example 28) relates to a previously-described example (e.g. one or more of examples 26-27), wherein the elongated wave structures define elongated channels between the heat spreading means and the phase-change heat transferring means, the elongated channels being configured to direct airflow between the heat spreading means and the phase-change heat transferring means.

Another example (e.g. example 29) relates to a previously-described example (e.g. e.g. one or more of examples 23-28), wherein the phase-change heat transferring means includes one or more support means extending between an upper phase-change heat transferring means layer and a lower phase-change heat transferring means layer, the one or more protrusions being aligned with the one or more support means.

Another example (e.g. example 30) relates to a previously-described example (e.g. one or more of examples 23-29), wherein the one or more protrusions are fastened to the phase-change heat transferring means.

Another example (e.g. example 31) relates to a previously-described example (e.g. one or more of examples 23-30), wherein the one or more protrusions are soldered to the phase-change heat transferring means.

An example (e.g. example 32) is a phase-change heat transferring device, comprising: a first layer; a second layer spaced from the first layer in a first direction to define a vapor zone between the first and the second layers; and one or more support means disposed in the phase-change heat transferring means and between the first and the second layers, wherein the second layer comprises one or more protrusions extending from a surface of the second layer in the first direction and configured to interface with at least a portion of the one or more support means.

Another example (e.g. example 33) relates to a previously-described example (e.g. example 32), wherein the first layer comprises one or more protrusions extending from a surface of the first layer in a second direction opposite the first direction.

Another example (e.g. example 34) relates to a previously-described example (e.g. example 33), wherein the one or more protrusions of the first layer are configured to interface with at least a portion of the one or more support means.

Another example (e.g. example 35) relates to a previously-described example (e.g. example 33), further comprising a second support member of the one or more support means, wherein the one or more protrusions of the first layer are configured to interface with at least a portion of the second support member.

Another example (e.g. example 36) relates to a previously-described example (e.g. example 33), wherein at least one protrusion of the one or more protrusions of the second layer is aligned with and disposed opposite to at least one corresponding protrusion of the one or more protrusions of the first layer.

Another example (e.g. example 37) relates to a previously-described example (e.g. example 33), wherein at least one of the one or more support means is a dual-sided support member having a first portion interfacing with a protrusion of the one or more protrusions of the first layer and a second portion interfacing with a protrusion of the one or more protrusions of the second layer.

Another example (e.g. example 38) relates to a previously-described example (e.g. one or more of examples 32-37), wherein the one or more protrusions are conical protrusions.

Another example (e.g. example 39) relates to a previously-described example (e.g. one or more of examples 32-38), wherein the one or more protrusions define corresponding cavities configured to receive at least the portion of the one or more support means.

Another example (e.g. example 40) relates to a previously-described example (e.g. one or more of examples 32-39), further comprising a heat spreading means disposed on and spaced from the surface of the second layer, wherein the one or more protrusions are configured to thermally couple the second layer to the heat spreading means.

Another example (e.g. example 41) relates to a previously-described example (e.g. example 40), wherein the one or more protrusions define one or more cavities between the heat spreading means and the second layer, the one or more cavities being configured to direct airflow between the second layer and the heat spreading means.

Another example (e.g. example 42) relates to a previously-described example (e.g. one or more of examples 32-41), wherein the one or more support means are configured to thermally couple the first and second layers together.

Another example (e.g. example 43) relates to a previously-described example (e.g. one or more of examples 32-42), wherein the one or more support means comprise a cylindrical body and at least one conical portion.

An example (e.g. example 44) is a heat transferring system, comprising: a phase-change heat transferring means including one or more protrusions extending from a first surface of the phase-change heat transferring means; and a heat spreading means disposed on the phase-change heat transferring means and including a second surface facing the first surface of the phase-change heat transferring means, wherein the second surface includes one or more protrusions extending from the second surface towards the first surface of the phase-change heat transferring means, the one or more protrusions of the heat spreading means and/or the one or more protrusions of the phase-change heat transferring means being configured to thermally couple the heat spreading means to the phase-change heat transferring means.

An example (e.g. example 45) is a heat transfer system as shown and described.

### CONCLUSION

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [. . . ], etc.). The term “a plurality” may be understood to include a numerical quantity greater than or equal to two (e.g., two, three, four, five, [. . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

1. A vapor chamber system, comprising:
a vapor chamber; and
a heat spreader disposed on the vapor chamber and including a surface facing the vapor chamber, wherein the surface includes one or more protrusions extending from the surface towards the vapor chamber, the one or more protrusions being configured to thermally couple the heat spreader to the vapor chamber.

2. The vapor chamber system of claim 1, wherein the one or more protrusions define one or more cavities between the heat spreader and the vapor chamber, the one or more cavities being configured to direct airflow between the heat spreader and the vapor chamber.

3. The vapor chamber system of claim 1, wherein the one or more protrusions are conical protrusions.

4. The vapor chamber system of claim 1, wherein the one or more protrusions comprise elongated wave structures extending across at least a portion of the surface of the heat spreader.

5. The vapor chamber system of claim 4, wherein the elongated wave structures include alternating upper portions and lower portions forming a corrugated pattern.

6. The vapor chamber system of claim 4, wherein the elongated wave structures define elongated channels between the heat spreader and the vapor chamber, the elongated channels being configured to direct airflow between the heat spreader and the vapor chamber.

7. The vapor chamber system of claim 1, wherein the vapor chamber includes one or more support members extending between an upper vapor chamber layer and a lower vapor chamber layer, the one or more protrusions being aligned with the one or more support members.

8. The vapor chamber system of claim 1, wherein the one or more protrusions are fastened to the vapor chamber.

9. A vapor chamber, comprising:
a first layer;
a second layer spaced from the first layer in a first direction to define a vapor zone between the first and the second layers; and
one or more support members disposed in the vapor chamber and between the first and the second layers,
wherein the second layer comprises one or more protrusions extending from a surface of the second layer in the first direction and configured to interface with at least a portion of the one or more support members.

10. The vapor chamber of claim 9, wherein the first layer comprises one or more protrusions extending from a surface of the first layer in a second direction opposite the first direction.

11. The vapor chamber of claim 10, wherein the one or more protrusions of the first layer are configured to interface with at least a portion of the one or more support members.

12. The vapor chamber of claim 10, further comprising a second support member of the one or more support members, wherein the one or more protrusions of the first layer are configured to interface with at least a portion of the second support member.

13. The vapor chamber of claim 10, wherein at least one protrusion of the one or more protrusions of the second layer is aligned with and disposed opposite to at least one corresponding protrusion of the one or more protrusions of the first layer.

14. The vapor chamber of claim 10, wherein at least one of the one or more support members is a dual-sided support member having a first portion interfacing with a protrusion of the one or more protrusions of the first layer and a second portion interfacing with a protrusion of the one or more protrusions of the second layer.

15. The vapor chamber of claim 9, wherein the one or more protrusions define corresponding cavities configured to receive at least the portion of the one or more support members.

16. The vapor chamber of claim 9, further comprising a heat spreader disposed on and spaced from the surface of the second layer, wherein the one or more protrusions are configured to thermally couple the second layer to the heat spreader.

17. The vapor chamber of claim 16, wherein the one or more protrusions define one or more cavities between the heat spreader and the second layer, the one or more cavities being configured to direct airflow between the second layer and the heat spreader.

18. The vapor chamber of claim 9, wherein the one or more support members are configured to thermally couple the first and second layers together.

19. The vapor chamber of claim 9, wherein the one or more support members comprise a cylindrical body and at least one conical portion.

20. A vapor chamber system, comprising:
a vapor chamber including one or more protrusions extending from a first surface of the vapor chamber; and
a heat spreader disposed on the vapor chamber and including a second surface facing the first surface of the vapor chamber, wherein the second surface includes one or more protrusions extending from the second surface towards the first surface of the vapor chamber, the one or more protrusions of the heat spreader and/or the one or more protrusions of the vapor chamber being configured to thermally couple the heat spreader to the vapor chamber.
